(19) United States
(12) Patent Application Publication
(10) Pub. No.: US 2009/0075477 A1
(43) Pub. Date: Mar. 19, 2009

(54) METHOD OF MANUFACTURING SEMICONDUCTOR DEVICE

(75) Inventors: Kazuo KAWAMURA, Musashino (JP); Shinichi AKIYAMA, Kawasaki (JP); Kazuya OKUBO, Kawasaki (JP); Akira KATAKAMI, Kawasaki (JP); Naoki IDANI, Kawasaki (JP); Takashi WATANABE, Yokkaichi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/207,998

(22) Filed: Sep. 10, 2008

(30) Foreign Application Priority Data
Sep. 19, 2007 (JP) 2007-243037

(51) Int. Cl. H01L 21/336

(52) U.S. Cl. 438/664; 257/E21.438

(57) ABSTRACT

According to an aspect of an embodiment, a method of manufacturing a semiconductor device has forming a silicon-containing layer over a semiconductor substrate, forming a metal layer over the semiconductor substrate and the silicon-containing layer, forming a silicide-containing layer over the semiconductor substrate and the silicon-containing layer by heat treatment of the semiconductor substrate and the silicon-containing layer, and applying flash annealing to the silicide-containing layer.

### CROSS-REFERENCE TO RELATED APPLICATION

This application is based upon and claims the benefit of priority of the prior Japanese Patent Application No. 2007-243037 filed on Sep. 19, 2007, the entire contents of which are incorporated herein by reference.

### BACKGROUND

1. Field

The embodiments discussed herein are directed to a method of manufacturing a semiconductor device including a silicide gate.

2. Description of Related Art

To reduce the electrical resistance of a gate electrode in a metal oxide semiconductor (MOS) transistor, in a certain developed technique, a metal, such as Ni, Ti, or Co, is deposited on the gate electrode to allow silicon in the gate electrode to react thermally with the metal, forming a silicide layer on the gate electrode. More recently, to further reduce the electrical resistance of a gate electrode, a so-called full silicidation process, in which the entire gate electrode is silicided, has been proposed.

The full silicidation process can be applied to a so-called salicide process, in which upper portions of source/drain regions, as well as a gate electrode, are also silicided. In the salicide process, the source/drain regions are silicided only in their upper portions, and the gate electrode is fully silicided. The salicide process may be performed as described below (see K. G. Anil, et al., 2004 Symposium on VLSI Technology Digest of Technical Papers, p. 190).

### SUMMARY

According to an aspect of an embodiment, a method of manufacturing a semiconductor device has forming a silicon-containing layer over a semiconductor substrate, forming a metal layer over the semiconductor substrate and the silicon-containing layer, forming a silicide-containing layer over the semiconductor substrate and the silicon-containing layer by heat treatment of the semiconductor substrate and the silicon-containing layer, and applying flash annealing to the silicide-containing layer.

### BRIEF DESCRIPTION OF THE DRAWINGS

FIGS. 1A to 1C are schematic cross-sectional views illustrating successive steps of a method of manufacturing a MOS transistor according to a first embodiment;

FIGS. 2A to 2C are schematic cross-sectional views illustrating successive steps of a method of manufacturing a MOS transistor according to the first embodiment, following the step illustrated in FIG. 1C;

FIGS. 3A to 3C are schematic cross-sectional views illustrating successive steps of a method of manufacturing a MOS transistor according to the first embodiment, following the step illustrated in FIG. 2C;

FIGS. 4A to 4C are schematic cross-sectional views illustrating successive steps of a method of manufacturing a MOS transistor according to the first embodiment, following the step illustrated in FIG. 3C;

FIGS. 5A to 5C are schematic cross-sectional views illustrating successive steps of a method of manufacturing a MOS transistor according to the first embodiment, following the step illustrated in FIG. 4C;

FIGS. 6A to 6C are schematic cross-sectional views illustrating successive steps of a method of manufacturing a MOS transistor according to the first embodiment, following the step illustrated in FIG. 5C;

FIGS. 7A to 7C are schematic cross-sectional views illustrating successive steps of a method of manufacturing a MOS transistor according to the first embodiment, following the step illustrated in FIG. 6C;

FIGS. 8A to 8C are schematic cross-sectional views illustrating successive steps of a method of manufacturing a MOS transistor according to the first embodiment, following the step illustrated in FIG. 7C;

FIGS. 9A to 9C are schematic cross-sectional views illustrating successive steps of a method of manufacturing a MOS transistor according to the first embodiment, following the step illustrated in FIG. 8C;

FIG. 10 is a schematic cross-sectional view illustrating a step of a method of manufacturing a MOS transistor according to the first embodiment, following the step illustrated in FIG. 9C;

FIGS. 11A to 11C are schematic cross-sectional views illustrating successive steps of a method of manufacturing a MOS transistor according to the first embodiment, following the step illustrated in FIG. 10;

FIGS. 12A and 12B are schematic cross-sectional views illustrating successive steps of a method of manufacturing a MOS transistor according to the first embodiment, following the step illustrated in FIG. 11C;

FIG. 13 is a schematic cross-sectional view illustrating a step of a method of manufacturing a MOS transistor according to the first embodiment, following the step illustrated in FIG. 12B;

FIG. 14 is a schematic cross-sectional view illustrating a step of a method of manufacturing a MOS transistor according to the first embodiment, following the step illustrated in FIG. 13;

FIG. 15 is a graph showing the relationship between the assist temperature and the radiation energy in flash lamp annealing;

FIG. 16 is a graph showing the relationship between the ON-state current and the OFF-state current (Iₒₙ-I_{off} curve) of a p-type MOS transistor manufactured according to the first embodiment;

FIGS. 17A to 17C are schematic cross-sectional views illustrating successive main steps of a method of manufacturing a MOS transistor according to a second embodiment;

FIGS. 18A to 18C are schematic cross-sectional views illustrating successive main steps of a method of manufacturing a MOS transistor according to the second embodiment, following the step illustrated in FIG. 17C;

FIGS. 19A to 19C are schematic cross-sectional views illustrating successive main steps of a method of manufacturing a MOS transistor according to the second embodiment, following the step illustrated in FIG. 18C;

FIG. 20 is a schematic cross-sectional view illustrating a main step of a method of manufacturing a MOS transistor according to the second embodiment, following the step illustrated in FIG. 19C;

FIG. 21 is a schematic cross-sectional view illustrating a main step of a method of manufacturing a MOS transistor according to the second embodiment, following the step illustrated in FIG. 20;

FIGS. 22A to 22C are schematic cross-sectional views illustrating successive main steps of a method of manufacturing a MOS transistor according to a third embodiment;

FIGS. 23A to 23C are schematic cross-sectional views illustrating successive main steps of a method of manufacturing a MOS transistor according to the third embodiment, following the step illustrated in FIG. 22C;

FIGS. 24A to 24C are schematic cross-sectional views illustrating successive main steps of a method of manufacturing a MOS transistor according to the third embodiment, following the step illustrated in FIG. 23C;

FIGS. 25A and 25B are schematic cross-sectional views illustrating successive main steps of a method of manufacturing a MOS transistor according to the third embodiment, following the step illustrated in FIG. 24C;

FIG. 26 is a schematic cross-sectional view illustrating a main step of a method of manufacturing a MOS transistor according to the third embodiment, following the step illustrated in FIG. 25B;

FIGS. 27A to 27C are schematic cross-sectional views illustrating successive main steps of a method of manufacturing a MOS transistor according to a fourth embodiment;

FIGS. 28A to 28C are schematic cross-sectional views illustrating successive main steps of a method of manufacturing a MOS transistor according to the fourth embodiment, following the step illustrated in FIG. 27C;

FIGS. 29A to 29C are schematic cross-sectional views illustrating successive main steps of a method of manufacturing a MOS transistor according to the fourth embodiment, following the step illustrated in FIG. 28C;

FIGS. 30A and 30B are schematic cross-sectional views illustrating successive main steps of a method of manufacturing a MOS transistor according to the fourth embodiment, following the step illustrated in FIG. 29C;

FIGS. 31A and 31B are schematic cross-sectional views illustrating successive main steps of a method of manufacturing a MOS transistor according to the fourth embodiment, following the step illustrated in FIG. 30B;

FIG. 32 is a schematic cross-sectional view illustrating a main step of a method of manufacturing a MOS transistor according to the fourth embodiment, following the step illustrated in FIG. 31B;

FIGS. 33A to 33C are schematic cross-sectional views illustrating successive main steps of a method of manufacturing a MOS transistor in which a known full silicidation process is applied to a salicide process; and

FIGS. 34A and 34B are schematic cross-sectional views illustrating successive main steps of a method of manufacturing a MOS transistor in which a known full silicidation process is applied to a salicide process, following the step illustrated in FIG. 33C.

### DESCRIPTION OF THE PREFERRED EMBODIMENTS

Preferred embodiments will be described in detail below with reference to the drawings. While the following embodiments exemplify MOS transistors (in a fourth embodiment, a complementary metal oxide semiconductor (CMOS) transistor) as semiconductor devices, the embodiments may also be applied to any semiconductor device that has a gate, such as various semiconductor memories. In the following embodiments, for convenience of explanation and illustration, the structure of a semiconductor device will be described together with a method of manufacturing the semiconductor device.

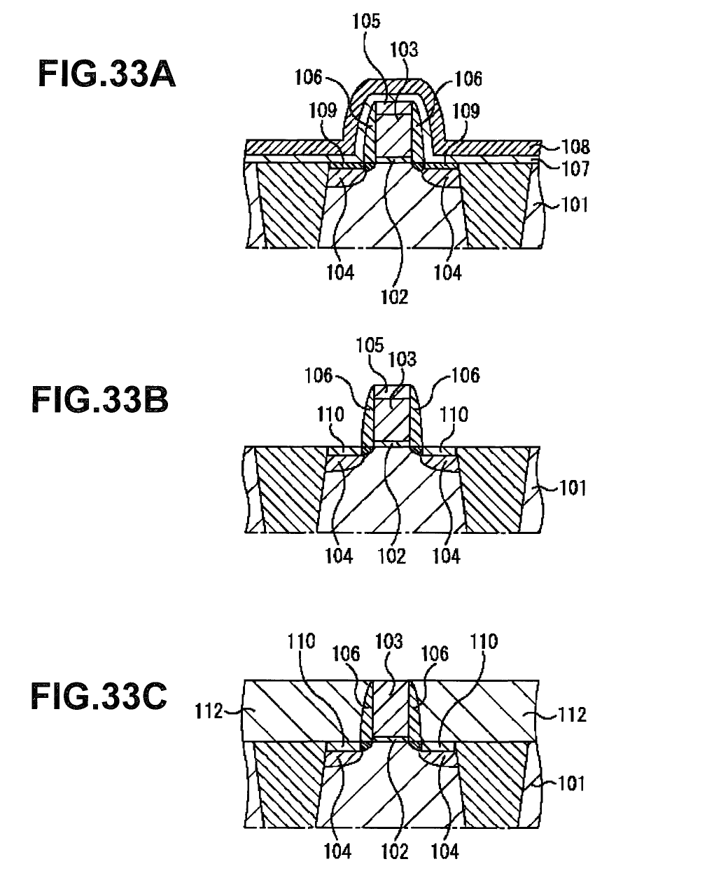

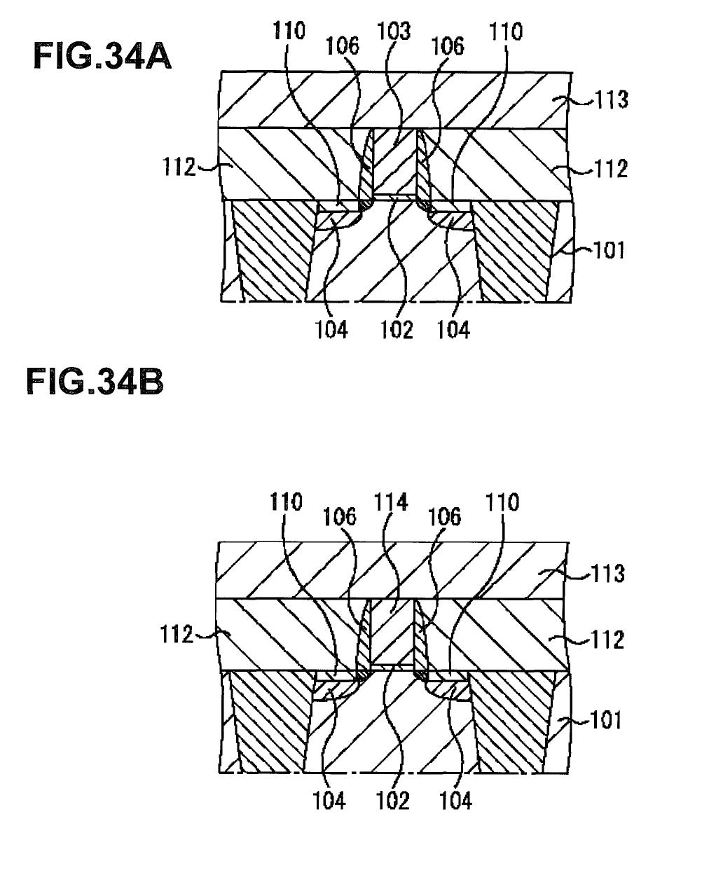

FIGS. 33A to 33C and FIGS. 34A and 34B are schematic cross-sectional views illustrating successive main steps of a method of manufacturing a MOS transistor in which a known full silicidation process is applied to a salicide process.

First, as illustrated in FIG. 33A, a polycrystalline silicon gate electrode 103 is formed on a gate insulating layer 102 disposed on a semiconductor substrate 101. The source/drain regions 104 are formed in the surface of the semiconductor substrate 101 at both sides of the gate electrode 103. A cap layer 105 formed, for example, of silicon nitride is disposed on the top of the gate electrode 103. Sidewall insulating layers 106 formed, for example, of silicon dioxide are disposed on the side faces of the gate electrode 103. A Ni alloy layer 107 formed of a metal capable of reacting with silicon to form a silicide (hereinafter referred to as silicide metal) and a TiN cap layer 108 are successively formed over the entire surface of the semiconductor substrate, and are heat-treated at a relatively low temperature (300° C. or less) (first silicidation). Ni₂Si (to be precise, (Ni alloy)₂Si) layers 109 are formed in the surfaces of the source/drain regions 104 by the heat treatment.

As illustrated in FIG. 33B, after an unreacted Ni alloy layer 107 and the TiN layer 108 are selectively removed by wet etching, heat treatment is performed at a relatively high temperature (about 300° C. to 450° C.) (second silicidation). The Ni₂Si layers 109 in the surfaces of the source/drain regions 104 are converted into NiSi (to be precise, (Ni alloy) Si) layers 110. The cap layer 105 disposed on the gate electrode 103 prevents the gate electrode 103 from being silicided in the first silicidation and the second silicidation.

As illustrated in FIG. 33C, after the cap layer 105 is selectively removed by wet etching, an insulating layer (for example, a protective layer 112 formed of silicon nitride) is deposited over the entire surface of the semiconductor substrate 101. The protective layer 112 has such a thickness that the gate electrode 103 is embedded in the protective layer 112. The protective layer 112 and the sidewall insulating layers 106 are subjected to chemical mechanical polishing (CMP) to expose the top surface of the gate electrode 103.

As illustrated in FIG. 34A, a Ni alloy layer 113 formed of a silicide metal is formed on the gate electrode 103 and the silicon nitride protective layer 112.

As illustrated in FIG. 34B, the gate electrode 103 is heat-treated, for example, at a temperature approximately in the range of 300° C. to 500° C. (400° C. in this case) to produce a fully silicided gate electrode 114 (third silicidation).

After an unreacted Ni alloy layer 113 is selectively removed by wet etching, a MOS transistor is produced through steps of the formation of contact holes and interlayer insulating layers, wiring, and the like.

However, when a known full silicidation process is applied to a salicide process, the protective layer 112, the gate electrode 103, and sidewall insulating layers 106 do not have sufficient flatness in the CMP planarization before the third silicidation.

More specifically, polycrystalline silicon of the gate electrode 103 and silicon dioxide of the sidewall insulating layers 106 have an etching rate higher than that of silicon nitride of the protective layer 112. After the CMP, therefore, the top surfaces of the gate electrode 103 and the sidewall insulating layers 106 are lower than the top surface of the protective layer 112. Thus, the protective layer 112, the gate electrode 103, and the sidewall insulating layers 106 have poor flatness.

The poor flatness causes the following problems.

First, the poor flatness increases the dependency of the amount of removed substance by abrasion of the surface of the protective layer 112 on the distribution of gate electrodes 103.

More specifically, in general, a plurality of gate electrodes 103 is nonuniformly distributed on the semiconductor substrate 101. When a silicon nitride layer covering the gate electrodes 103 is subjected to CMP, the difference in etching rate causes a difference in the amount of removed substance by abrasion of the surface of the protective layer 112 between an area in which the gate electrodes are contained in high density and an area in which the gate electrodes are contained in low density.

Second, the poor flatness increases the dependency of the amount of removed substance by abrasion of the surface of the protective layer 112 on the line width (gate length) of the gate electrode 103.

A plurality of gate electrodes 103 may have different line widths (gate lengths) depending on their characteristics. The difference in etching rate causes a difference in the amount of removed substance by abrasion of the surface of the protective layer 112 between gate electrodes 103 having a longer gate length and those having a shorter gate length.

The difference in the amount of removed substance by abrasion of the surface of the protective layer 112 causes a difference in the contact area between a silicide metal and a gate electrode 103 in a full silicidation process, resulting in nonuniform silicidation. The nonuniform silicidation of the gate electrode 103 makes the practical use of the MOS transistor difficult.

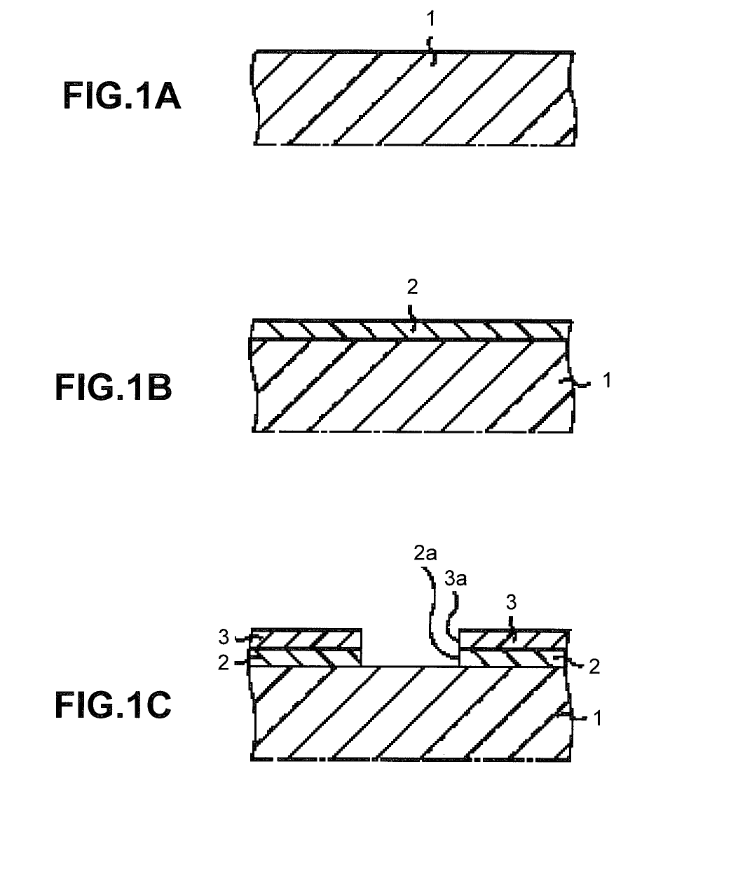

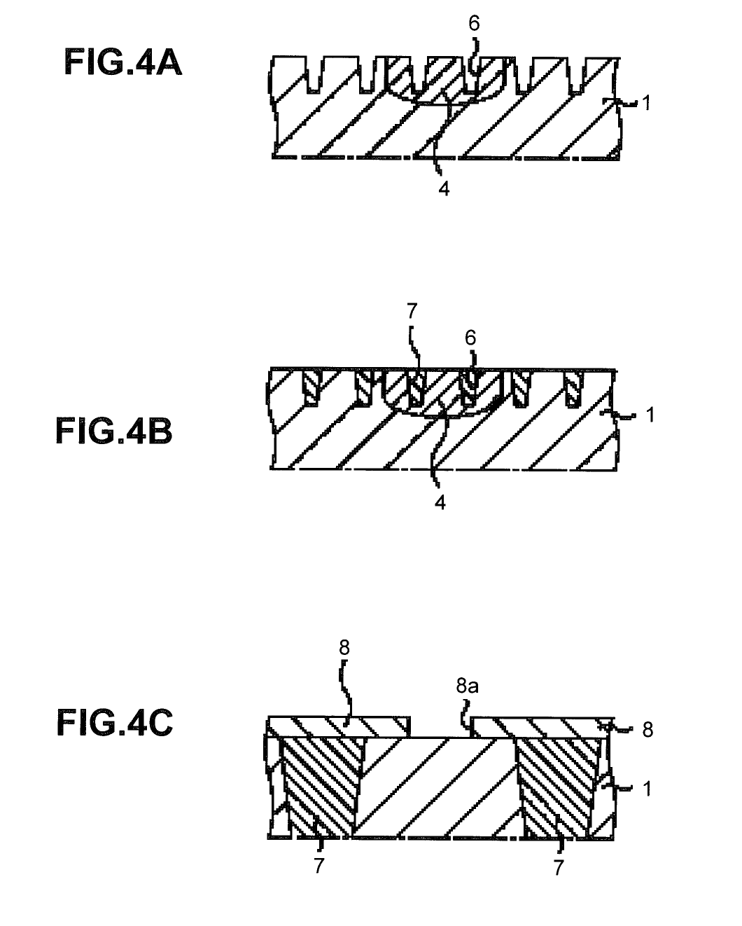

FIGS. 1 to 14 are schematic cross-sectional views illustrating the successive steps of a method of manufacturing a MOS transistor according to a first embodiment. FIGS. 4C to FIG. 14 are enlarged views of an active region between adjacent device isolation regions for shallow trench isolation (STI).

First, as illustrated in FIG. 1A, a semiconductor substrate 1 formed of a p-type single-crystal silicon having a (100) plane is washed with ammonia and hydrogen peroxide.

Second, as illustrated in FIG. 1B, the semiconductor substrate 1 is thermally oxidized to grow a silicon dioxide layer 2 having a thickness of about 50 nm.

Third, as illustrated in FIG. 1C, a resist (not shown) is applied to the silicon dioxide layer 2, and a resist mask 3 having an opening 3a through which a well described below is to be exposed is formed by lithography. The silicon dioxide layer 2 is then dry-etched using the resist mask 3 to form an opening 2a, which is flush with the opening 3a.

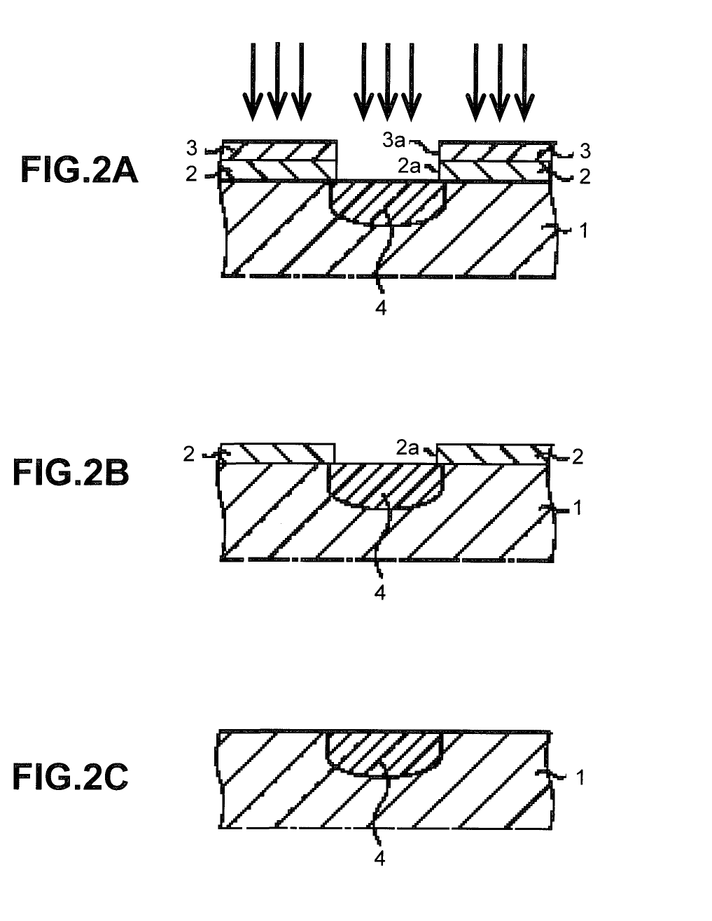

As illustrated in FIG. 2A, a well 4 is formed in the surface of the semiconductor substrate 1.

More specifically, the surface of the semiconductor substrate 1 is doped with an impurity introduced through the opening 2a and the opening 3a to form the well 4. For example, to form a p-type well, boron ions (B⁺) may be implanted at an acceleration energy of 120 keV and a dose of 1.0×10¹³/cm². To form an n-type well, phosphorus ions (P⁺) may be implanted at an acceleration energy of 300 keV and a dose of 1.0×10¹³/cm².

After the resist mask 3 is removed, for example, by ashing, as illustrated in FIG. 2B, the silicon dioxide layer 2 is removed by wet etching, as illustrated in FIG. 2C.

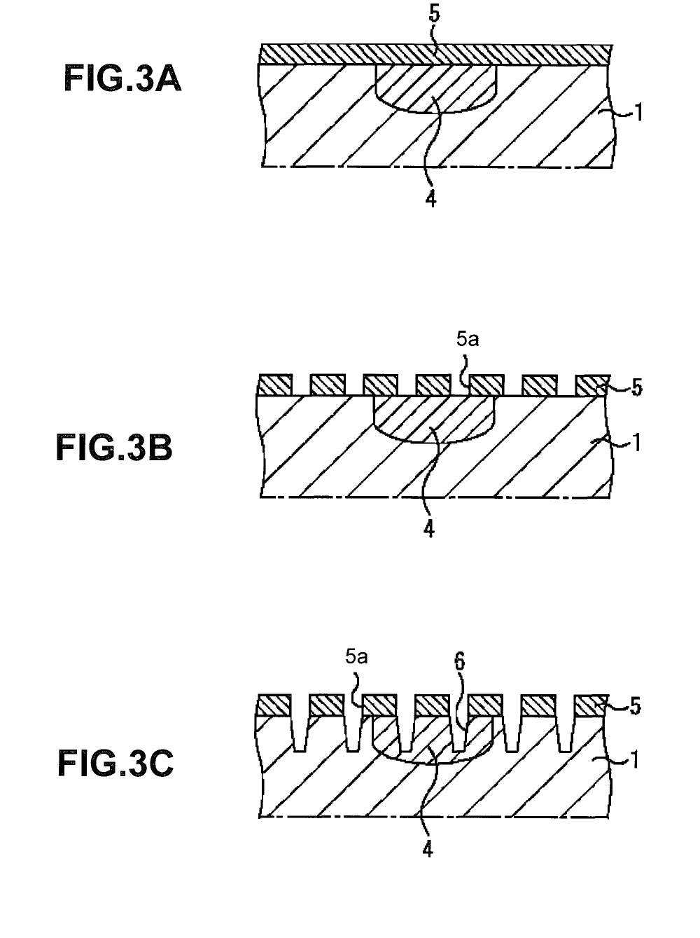

As illustrated in FIG. 3A, a silicon nitride layer 5 having a thickness of about 50 nm is formed over the entire surface of the semiconductor substrate 1, for example, by chemical vapor deposition (CVD).

As illustrated in FIG. 3B, the silicon nitride layer 5 is subjected to lithography and dry etching to form openings 5a through which device isolation regions in the surface of the semiconductor substrate 1 are to be exposed.

As illustrated in FIG. 3C, the surfaces of the semiconductor substrate 1 in the openings 5a are dry-etched using the silicon nitride layer 5 as a mask to form isolation trenches 6.

As illustrated in FIG. 4A, the silicon nitride layer 5 is removed by wet etching.

As illustrated in FIG. 4B, device isolation regions 7 for STI that define active regions are formed on the semiconductor substrate 1.

More specifically, an insulating layer formed of silicon dioxide is deposited over the entire surface of the semiconductor substrate 1, for example, by CVD to fill the isolation trenches 6 with silicon dioxide. The silicon dioxide insulating layer is then removed from the surface of the semiconductor substrate 1 by CMP to form the device isolation regions 7 for STI, which are the isolation trenches 6 filled with silicon dioxide.

As illustrated in FIG. 4C, a resist (not shown) is applied to the semiconductor substrate 1, and a resist mask 8 having an opening 8a through which part of an active region between adjacent device isolation regions 7 for STI is exposed is formed by lithography.

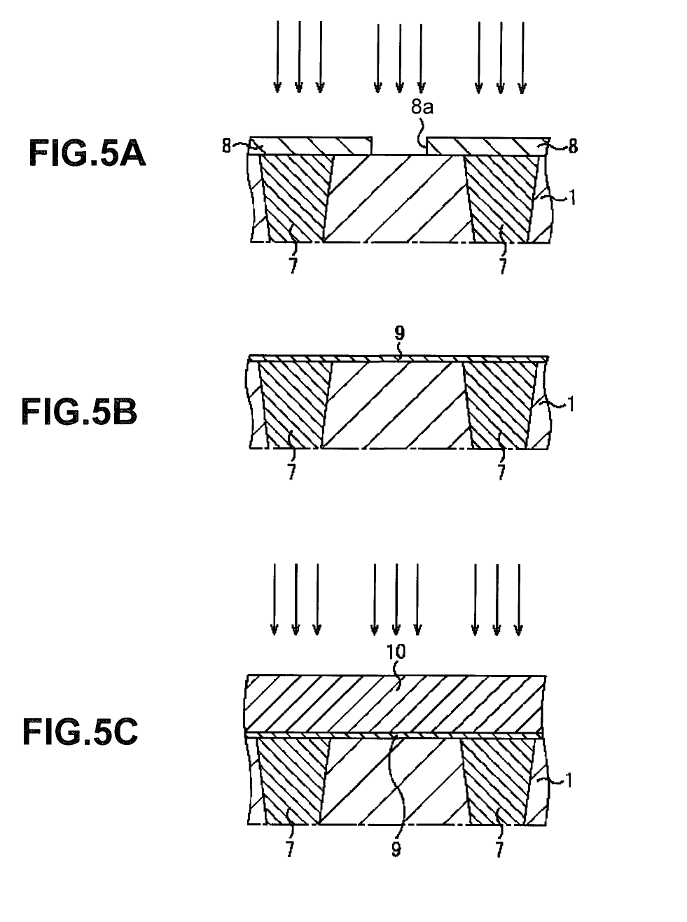

As illustrated in FIG. 5A, the active region in the semiconductor substrate 1 is subjected to channel dose ion implantation for threshold control. For example, to manufacture an n-type MOS transistor, boron ions (B⁺) may be implanted at an acceleration energy of 15 keV and a dose of 1.0×10¹³/cm². To manufacture a p-type MOS transistor, arsenic ions (As⁺) may be implanted at an acceleration energy of 80 keV and a dose of 1.0×10¹³/cm².

After the resist mask 8 is removed, for example, by ashing, the introduced impurity is activated by annealing, for example, at a temperature of 950° C. for 10 seconds. As illustrated in FIG. 5B, a gate insulating layer 9 formed of silicon dioxide is formed on the semiconductor substrate 1, for example, by CVD. The gate insulating layer 9 has a thickness of about 2 nm.

As illustrated in FIG. 5C, a polycrystalline silicon layer 10 having a thickness of about 100 nm is formed on the gate insulating layer 9, for example, by CVD. The polycrystalline silicon layer 10 is then doped with an impurity. For example, to manufacture a p-type MOS transistor, boron ions (B⁺) may be implanted at an acceleration energy of 5 keV and a dose of 1.0×10¹⁵/cm². To form an n-type MOS transistor, phosphorus ions (P⁺) may be implanted at an acceleration energy of 10 keV and a dose of 1.0×10¹⁶/cm².

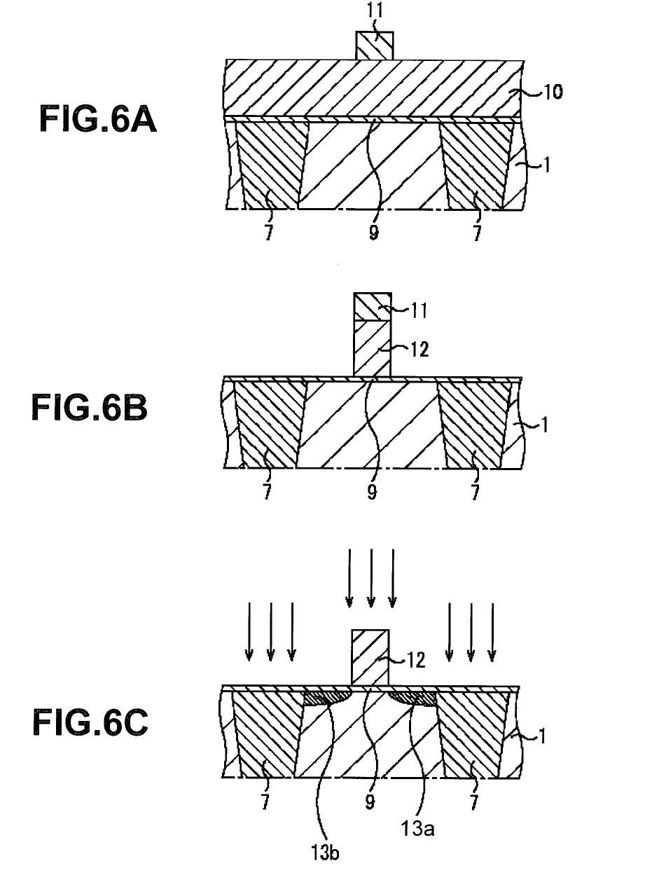

As illustrated in FIG. 6A, a resist (not shown) is applied to the polycrystalline silicon layer 10, and a resist mask 11 having a shape of an electrode is formed by lithography.

As illustrated in FIG. 6B, the polycrystalline silicon layer 10 is dry-etched using the resist mask 11 to form a gate electrode 12.

As illustrated in FIG. 6C, after the resist mask 11 is removed, for example, by ashing, extension regions 13a and 13b are formed in the surface of the semiconductor substrate 1.

More specifically, an impurity is introduced into the surface of the semiconductor substrate 1 at both sides of the gate electrode 12 using the gate electrode 12 as a mask to form the extension regions 13a and 13b. For example, to manufacture a p-type MOS transistor, boron ions (B⁺) may be implanted at an acceleration energy of 0.5 keV and a dose of 1.0×10¹⁵/cm². To form an n-type MOS transistor, arsenic ions (As⁺) may be implanted at an acceleration energy of 1 keV and a dose of 1.0×10¹⁵/cm².

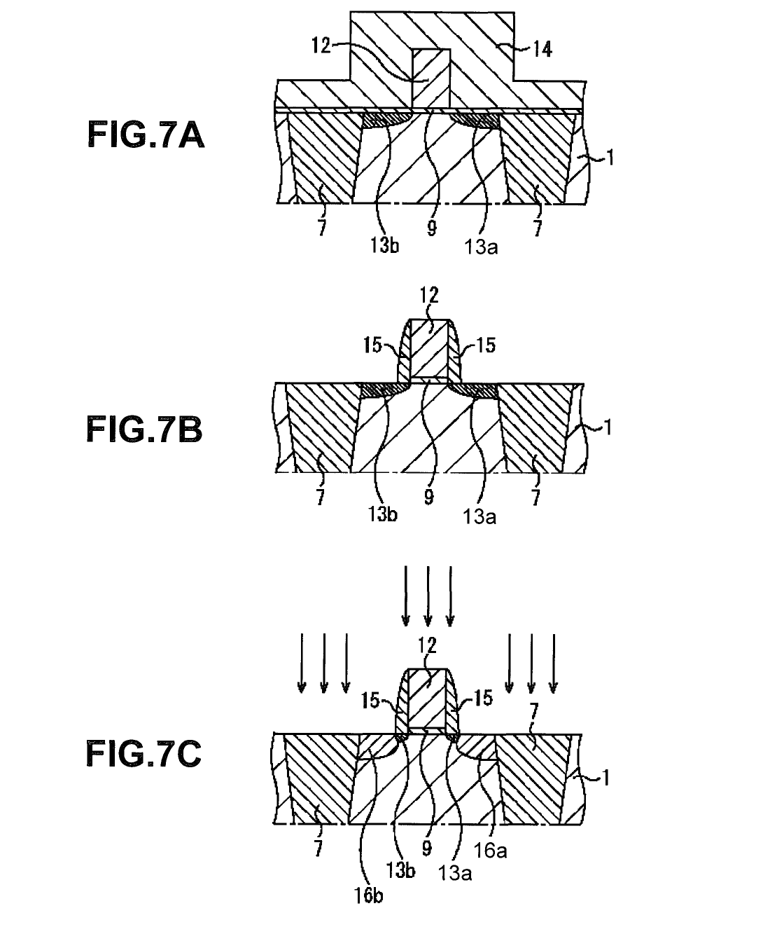

As illustrated in FIG. 7A, an insulating silicon dioxide layer 14 having a thickness of about 100 nm is formed, for example, by CVD to cover the semiconductor substrate 1 and the gate electrode 12.

As illustrated in FIG. 7B, the silicon dioxide layer 14 is anisotropically dry-etched by reactive ion etching (RIE) to leave silicon dioxide on both sides of the gate electrode 12, thus forming sidewall insulating layers 15.

As illustrated in FIG. 7C, source/drain regions 16a and 16b are formed in the surface of the semiconductor substrate 1. The source/drain regions 16a and 16b overlap with the extension regions 13a and 13b.

More specifically, an impurity is introduced into the surface of the semiconductor substrate 1 at both sides of the gate electrode 12 using the gate electrode 12 and the sidewall insulating layers 15 as a mask to form the source/drain regions 16a and 16b. For example, to manufacture a p-type MOS transistor, boron ions (B⁺) may be implanted at an acceleration energy of 5 keV and a dose of 5.0×10¹⁵/cm². To form an n-type MOS transistor, phosphorus ions (P⁺) may be implanted at an acceleration energy of 8 keV and a dose of 1.0×10¹⁶/cm².

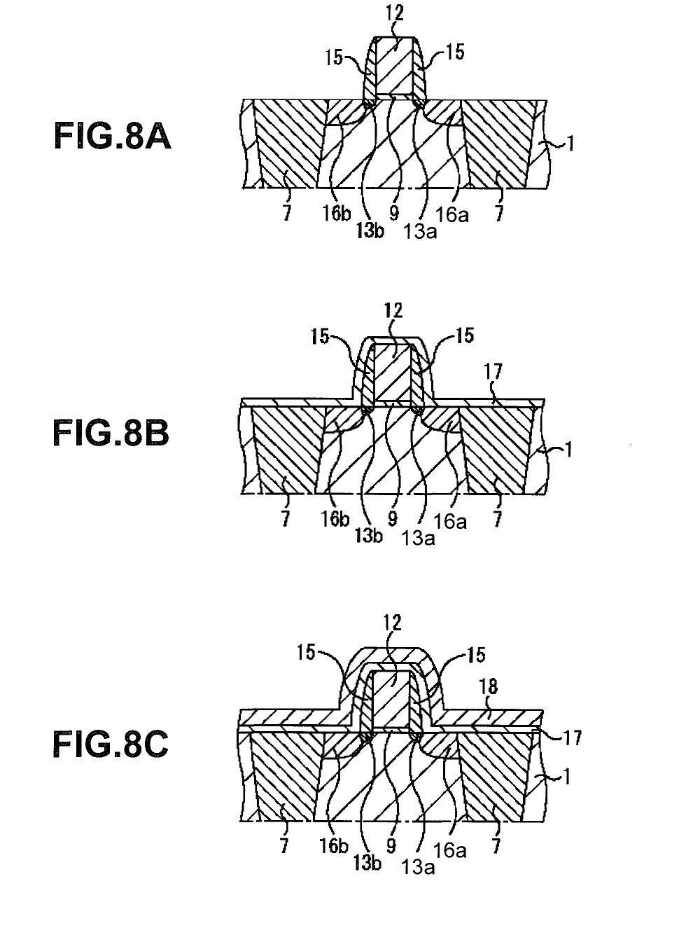

As illustrated in FIG. 8A, the introduced impurity is activated by annealing, for example, at a temperature of 1025° C. for 3 seconds.

As illustrated in FIG. 8B, a Ni alloy layer 17 formed of a silicide metal is formed.

More specifically, first, a natural oxidation layer created on the gate electrode 12 and on the source/drain regions 16a and 16b is removed using hydrofluoric acid.

An alloy target of silicide metal Ni is then prepared. The alloy target contains Ni and at least one element selected from the group consisting of Pt, Ta, W, Re, Y, Yb, Al, La, and Ti. The alloy target is NiPt in the present embodiment. The Pt content (concentration) in the target is in the range of 1 atomic % to 10 atomic % and preferably in the range of 2 atomic % to 10 atomic %, and is 5 atomic % in the present embodiment.

The Ni alloy layer 17 having a thickness of about 20 nm is deposited on the semiconductor substrate 1, the gate electrode 12, and the sidewall insulating layers 15 by sputtering using the target. The Ni alloy layer 17 may be formed by electron-beam evaporation instead of sputtering. The Ni alloy layer 17 may have a thickness of at least 17 nm and practically at most about 200 nm.

As illustrated in FIG. 8C, a TiN cap layer 18 having a thickness approximately in the range of 5 nm to 50 nm is formed on the Ni alloy layer 17, for example, by sputtering.

The cap layer 18 may be a Ti layer having a thickness approximately in the range of 5 nm to 30 nm. In some cases, the cap layer 18 may be unnecessary.

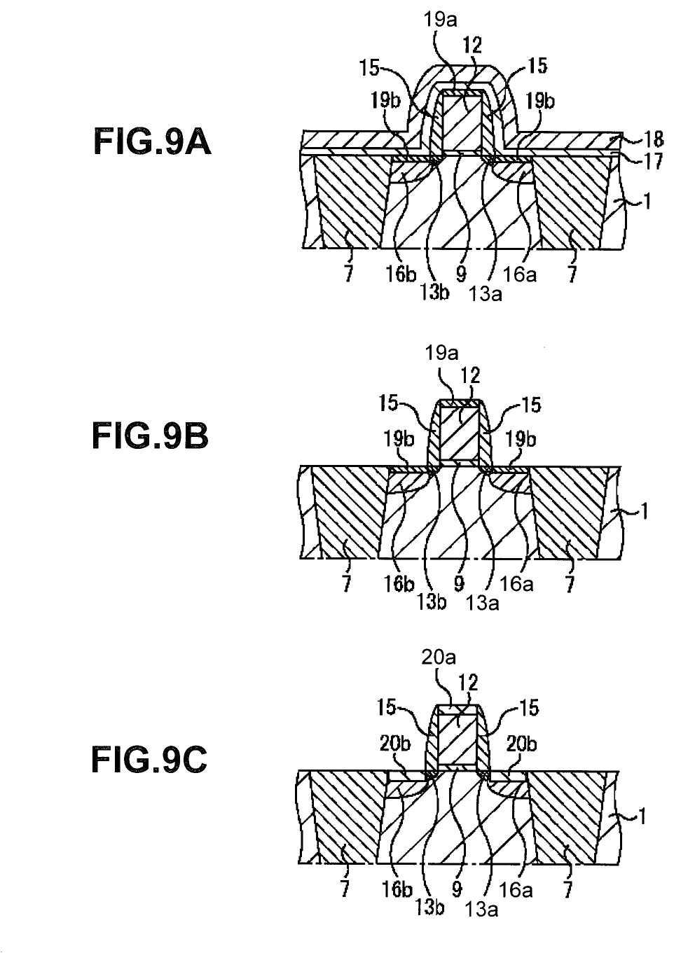

As illustrated in FIG. 9A, the top surface of the gate electrode 12 and the surfaces of the source/drain regions 16a and 16b are silicided to form (NiPt)₂Si layers 19a and 19b.

More specifically, the top surface of the gate electrode 12 and the surfaces of the source/drain regions 16a and 16b are silicided by rapid annealing at a relatively low temperature (300° C. or less, for example, 270° C.) for 30 seconds (first silicidation) to form the (NiPt)₂Si layer 19a in the gate electrode 12 and the (NiPt)₂Si layers 19b in the source/drain regions 16a and 16b. The rapid annealing may be replaced with furnace annealing (or furnace annealing +rapid heating).

As illustrated in FIG. 9B, the cap layer 18 and an unreacted Ni alloy layer 17 are selectively removed by a chemical treatment with a processing liquid composed of 3:1 sulfuric acid:hydrogen peroxide solution (hereinafter referred to as SPM treatment). The processing liquid may be composed of hydrochloric acid and a hydrogen peroxide solution.

As illustrated in FIG. 9C, the top surface of the gate electrode 12 and the surfaces of the source/drain regions 16a and 16b are further silicided to form (NiPt)Si layers 20a and 20b.

More specifically, the top surface of the gate electrode 12 and the surfaces of the source/drain regions 16a and 16b are further silicided by rapid annealing at a relatively high temperature (350° C. to 600° C., for example, 400° C.) for 10 to 120 seconds (for example, 30 seconds) (second silicidation) to convert the (NiPt)₂Si layers 19a and 19b into the (NiPt)Si layers 20a and 20b.

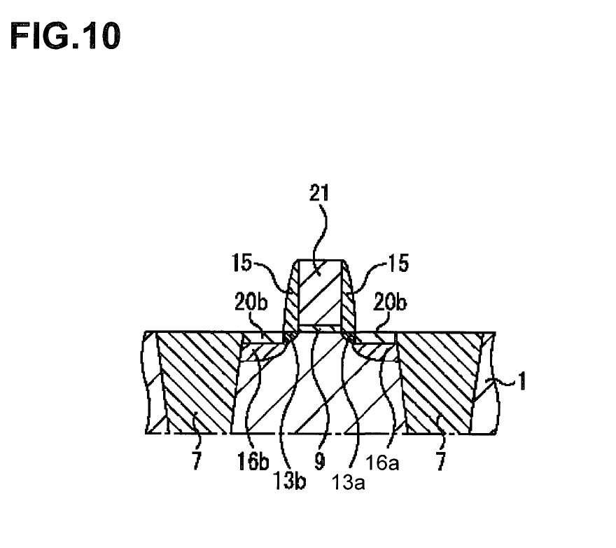

As illustrated in FIG. 10, flash lamp annealing is performed to form a fully silicided gate electrode 21 while the (NiPt)Si layers 20b are maintained on the source/drain regions 16a and 16b.

This selective full silicidation is probably effected due to the structure in which the surroundings of the source/drain regions 16a and 16b radiate heat easily while the surroundings of the gate electrode 12 retain heat in the flash lamp annealing.

More specifically, since the gate electrode 12 is thermally insulated by the surrounding gate insulating layer 9 and sidewall insulating layers 15, the silicidation of the gate electrode 12 is promoted by the flash lamp annealing. By contrast, the source/drain regions 16a and 16b radiate heat easily in the depth direction of the semiconductor substrate 1 (thermal conductivity: Si=148 W/mK=35.3×10⁻² cal cm⁻¹s^{-1° C.}⁻¹; SiO₂=2.55×10⁻² cal cm⁻¹s^{-1° C.}⁻¹ (in a direction of a C axis), 1.48×10⁻² cal cm⁻¹s^{-1° C.}⁻¹ (in a direction perpendicular to the C axis)), and are therefore heated negligibly as compared with the gate electrode 12. This prevents silicidation of the source/drain regions 16a and 16b. While the sidewalls are formed of silicon dioxide in the present embodiment, other insulating layers, such as silicon nitride layers or a laminate of a silicon dioxide layer and a silicon nitride layer, may also be used in the present embodiment.

The conditions for flash lamp annealing are as follows: radiation energy=24 to 28 J/cm², radiation time=0.5 to 1.5 ms, and assist temperature (holding temperature of the semiconductor substrate 1)=300° C. to 450° C.

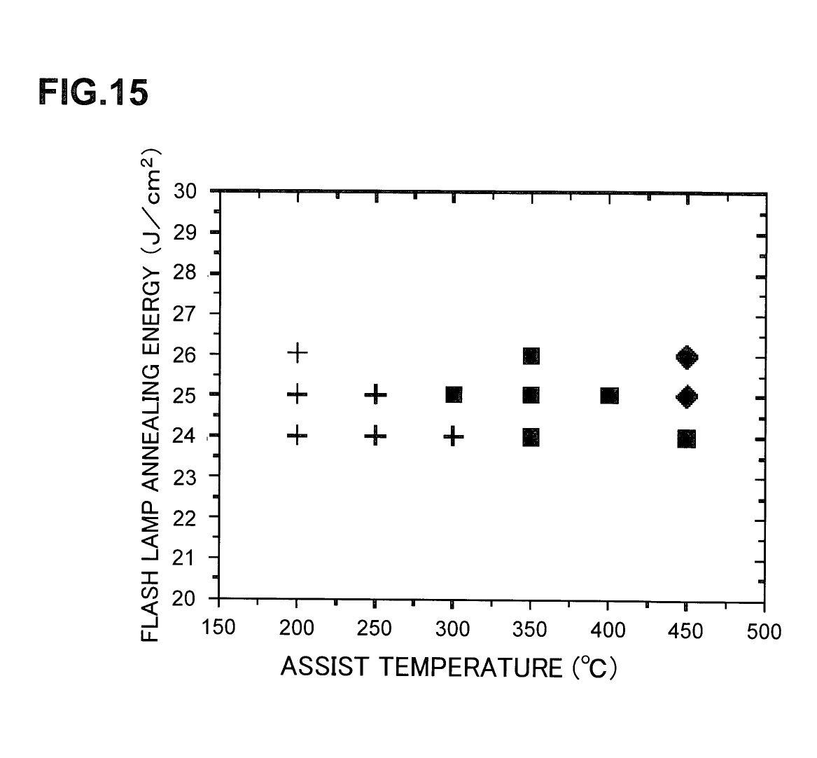

FIG. 15 shows the relationship between the assist temperature and the radiation energy in the flash lamp annealing. Silicidation was not achieved sufficiently at an assist temperature of 250° C. or less. At an assist temperature of 300° C., silicidation was achieved sufficiently at a radiation energy of 25 J. At an assist temperature of 350° C. or more, full silicidation was achieved even at a lower radiation energy. At an assist temperature of 450° C., silicidation was appropriately performed at a radiation energy of 24 J. However, at a radiation energy of 25 J or more, silicide began to agglomerate. The conditions for flash lamp annealing described above (assist temperature=300° C. to 450° and radiation energy=24 to 28 J/cm²) are based on the results shown in FIG. 15. The radiation time is preferably in the range of 0.5 ms to 1.5 ms as described above, because a radiation time of less than 0.5 ms may cause the warping of a wafer, and a radiation time of more than 1.5 ms may cause diffusion or deactivation of an impurity. In the present embodiment, flash lamp annealing is performed at an assist temperature of 450° C., a radiation energy of 24 J/cm², and a radiation time of 0.8 ms.

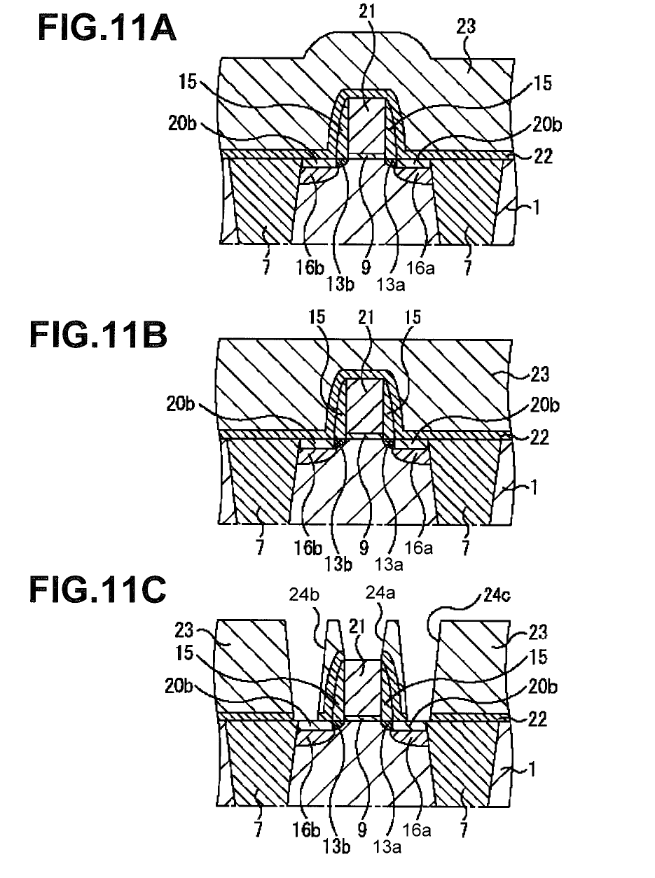

In the following steps (FIGS. 11A to FIG. 14), the processing temperature is 500° C. or less to prevent the agglomeration of (NiPt)Si in the fully silicided gate electrode 21.

As illustrated in FIG. 11A, a silicon nitride layer 22 is formed on the semiconductor substrate 1, the gate electrode 12, and the sidewall insulating layers 15. The silicon nitride layer 22 is formed at 400° C., for example, by CVD and has a thickness of about 50 nm. The silicon nitride layer 22 functions as an etching stopper, as described below.

A silicon dioxide layer 23 is formed on the silicon nitride layer 22. The silicon dioxide layer 23 is formed at 400° C., for example, by plasma CVD and has a thickness of about 600 nm.

As illustrated in FIG. 11B, the surface of the silicon dioxide layer 23 is flattened, for example, by CMP.

As illustrated in FIG. 11C, the silicon dioxide layer 23 and the silicon nitride layer 22 are subjected to lithography and dry etching to form a connecting hole 24a through which part of the gate electrode 12 is exposed and connecting holes 24b and 24c through which part of the source/drain regions 16a and 16b are exposed. In the dry etching, the silicon nitride layer 22 functions as an etching stopper to prevent unintentional over-etching of the gate electrode 12 and the source/drain regions 16a and 16b.

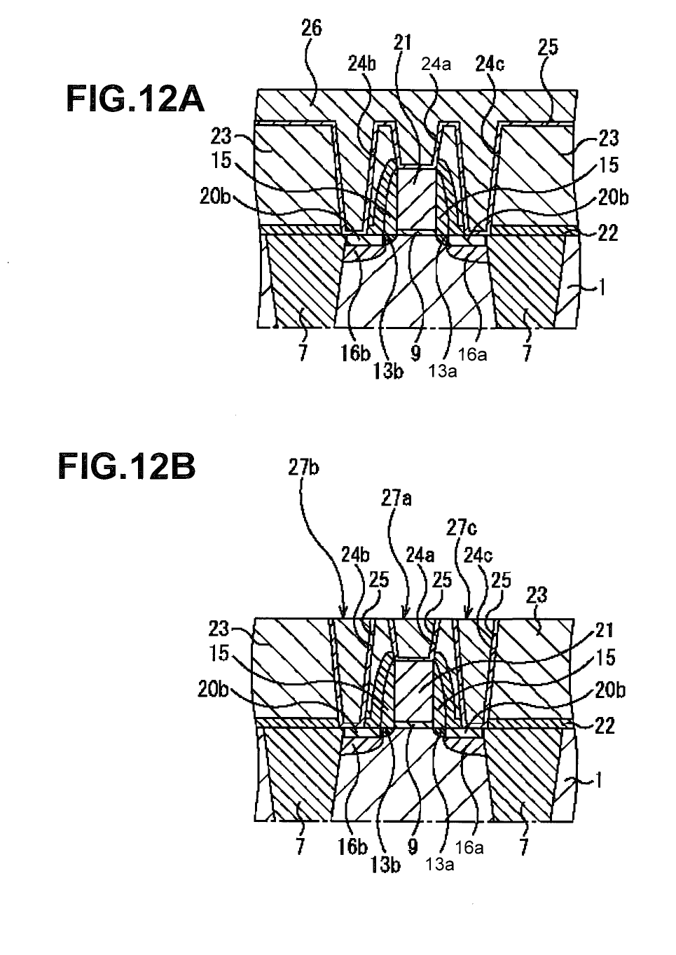

As illustrated in FIG. 12A, an underlying layer 25 and a W layer 26 are formed on the silicon dioxide layer 23. The W layer 26 fills the connecting holes 24a 24b and 24c via the underlying layer 25.

More specifically, first, the underlying layer 25 is formed on the silicon dioxide layer 23, for example, by depositing a Ti layer having a thickness of about 10 nm and a TiN layer having a thickness of about 50 nm on the inner walls of the connecting holes 24a 24b and 24c by sputtering.

The W layer 26 formed of an electroconductive material is formed on the underlying layer 25 to fill the connecting holes 24a 24b and 24c for example, by CVD. The W layer 26 has a thickness of about 300 nm at the narrowest portion.

As illustrated in FIG. 12B, the W layer 26 is polished, for example, by CMP to expose the top surface of the silicon dioxide layer 23. This polishing leaves connecting plugs 27a, 27b, and 27c in the connecting holes 24a 24b and 24c.

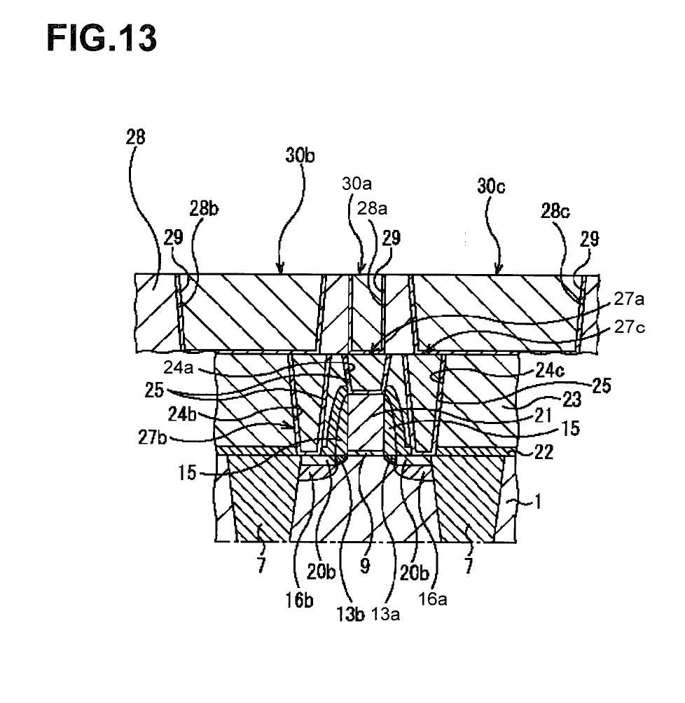

As illustrated in FIG. 13, an interlayer insulating layer 28 and wires 30a, 30b, and 30c are formed.

More specifically, first, the silicon dioxide interlayer insulating layer 28 is formed on the connecting plugs 27a, 27b, and 27c and the silicon dioxide layer 23, for example, by CVD.

Second, a so-called damascene process, a single damascene process in the present embodiment, is performed. The interlayer insulating layer 28 is subjected to lithography and dry etching to form trenches 28a, 28b, and 28c in the interlayer insulating layer 28. The underlying layer 29 is formed, for example, by depositing Ta on the inner walls of the trenches 28a, 28b, and 28c. Cu or a Cu alloy (not shown) is deposited on the underlying layer 29, for example, by plating to fill the trenches 28a, 28b, and 28c. The Cu or the Cu alloy is polished, for example, by CMP to expose the top surface of the interlayer insulating layer 28. This polishing leaves the wires 30a, 30b, and 30c, in the trenches 28a, 28b, and 28c, that are formed of Cu or the Cu alloy and are connected to the connecting plugs 27a, 27b, and 27c.

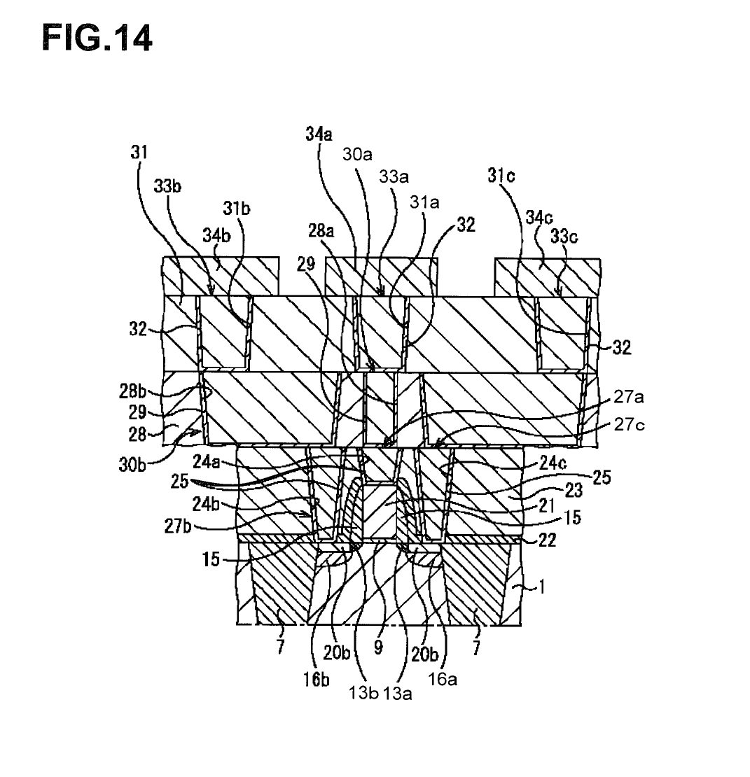

As illustrated in FIG. 14, after an interlayer insulating layer 31 is formed by the same step as in FIG. 13, via-holes 31a, 31b, and 31c are formed in the interlayer insulating layer 31. Cu or a Cu alloy is deposited on an underlying layer 32 formed, for example, of Ta to fill via-holes 31a, 31b, and 31c, thus forming via portions 33a, 33b, and 33c connected to the wires 30a, 30b, and 30c. Wires 34a 34b and 34c formed, for example, of Al or an Al alloy are formed on the interlayer insulating layer 31. The wires 34a 34b and 34c are connected to the via portions 33a, 33b, and 33c, respectively.

After additional steps, including a step of forming a protective layer (not shown), a MOS transistor according to the present embodiment is manufactured.

Since the fully silicided gate electrode 21 in the MOS transistor is formed by flash lamp annealing, as described above, the gate electrode 21 includes a silicon-rich NiSi₂ phase. This brings about the formation of a NiSi₂-containing layer between the fully silicided gate electrode 21 and the gate insulating layer 9.

When the MOS transistor is a p-type MOS transistor, to improve the transistor characteristics, the semiconductor substrate may be a SiGe substrate or a semiconductor substrate that includes SiGe layers in the source/drain regions, in place of the silicon substrate. When the MOS transistor is an n-type MOS transistor, to improve the transistor characteristics, the semiconductor substrate may be a SiCₓ substrate (0<x) or a semiconductor substrate that includes SiCₓ layers in the source/drain regions, in place of the silicon substrate.

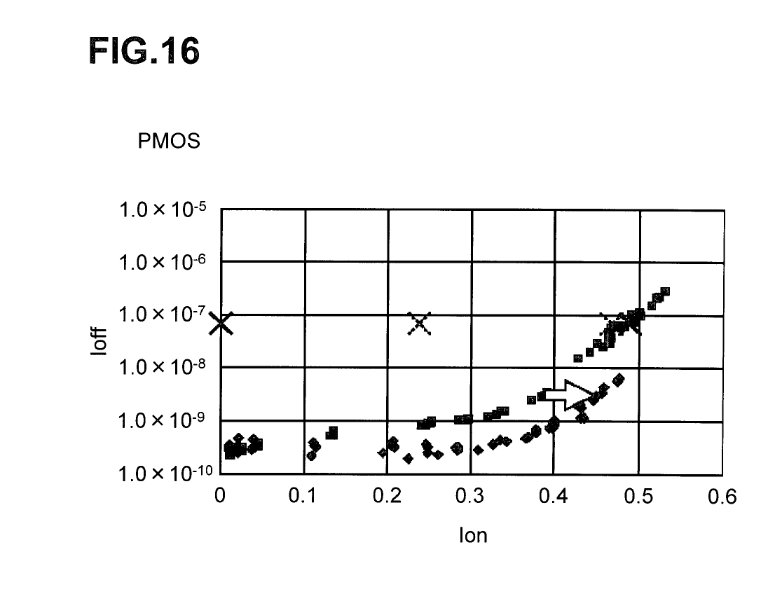

FIG. 16 shows the relationship between the ON-state current and the OFF-state current (Iₒₙ-I_{off} curve) of a p-type MOS transistor manufactured according to the present embodiment. An Iₒₙ-I_{off} curve of filled squares was obtained with a p-type MOS transistor according to a related art. An Iₒₙ-I_{off} curve of filled rhombuses was obtained with a p-type MOS transistor according to the present embodiment. This graph demonstrates that the p-type MOS transistor according to the present embodiment is improved in driving current by about 10% relative to the p-type MOS transistor according to a related art.

Furthermore, the present embodiment does not require a step of forming and removing a protective layer (for example, the protective layer 112 in FIG. 33C) required in a related art. More specifically, the present embodiment does not require a step of forming and removing protective layers covering side faces of a gate electrode in full silicidation of the gate electrode, thus reducing the number of steps. In addition, because other steps associated with the step of forming and removing protective layers of gate electrodes are also unnecessary, uniform and satisfactory full silicidation of the gate electrodes can be achieved without considering the effects of the distribution or the line width (gate length) of the gate electrodes.

Furthermore, unlike a related art, the present embodiment does not require a step of forming a cap layer (for example, the cap layer 105 in FIG. 33A) of a gate electrode, thus reducing the number of steps. In addition, ion implantation to the gate electrode (in the present embodiment, for example, ion implantation in FIG. 5A and simultaneous ion implantation in FIGS. 6C and 7C) allows for fine and easy threshold control.

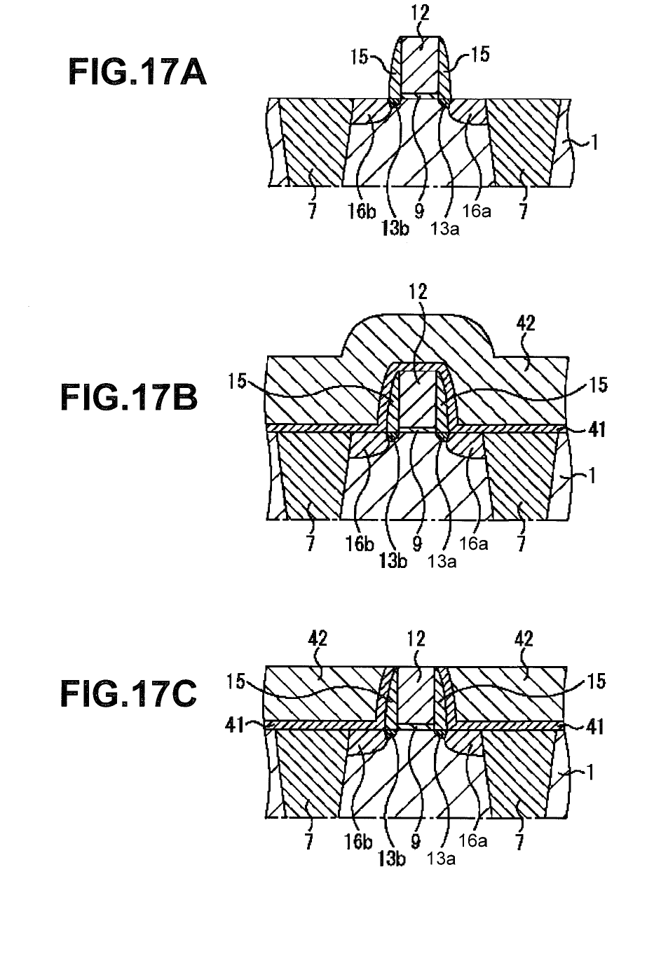

FIGS. 17 to 21 are schematic cross-sectional views illustrating the successive main steps of a method of manufacturing a MOS transistor according to a second embodiment. These drawings are enlarged views of an active region between adjacent device isolation regions for STI.

The step illustrated in FIG. 17A (identical with FIG. 8A) follows the steps in the first embodiment illustrated in FIGS. 1A to 8A.

As illustrated in FIG. 17B, a TiN layer 41 and a W layer 42 are successively formed.

More specifically, first, the TiN layer 41 having a thickness of about 50 nm is formed on the semiconductor substrate 1, the gate electrode 12, and the sidewall insulating layers 15, for example, by sputtering (so-called self-ionized plasma (SIP) sputtering in the present embodiment).

Second, an electroconductive layer, such as a W-containing (W or a W alloy) electroconductive layer, (the W layer 42 having a thickness of about 200 nm in the present embodiment) is formed on the TiN layer 41, for example, by CVD. The W layer 42 is formed of a non-silicide metal and has sufficient flatness in subsequent CMP.

As illustrated in FIG. 17C, the W layer 42 and the TiN layer 41 are polished, for example, by CMP to expose the top surface of the gate electrode 12.

A difference in etching rate between W and polycrystalline silicon of the gate electrode 12 is smaller than that between silicon nitride and polycrystalline silicon. Furthermore, w is superior in filling characteristics to silicon nitride. Thus, the W layer 42 has excellent flatness after CMP, without being affected significantly by the distribution or the line width (gate length) of the gate electrodes 12 in CMP.

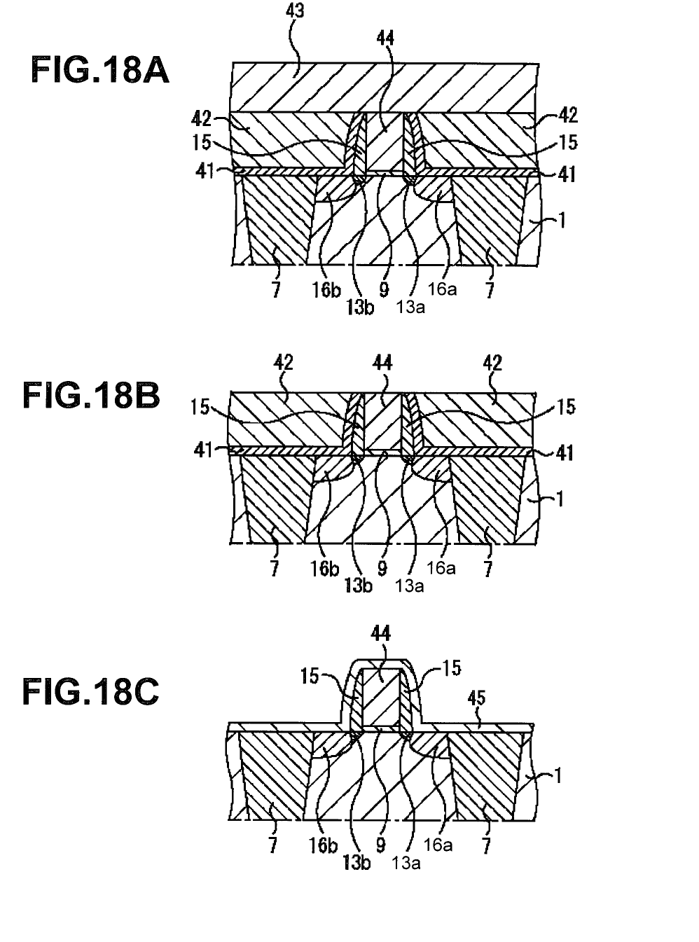

As illustrated in FIG. 18A, a Ni alloy layer 43, which is a silicide metal layer, is formed on the gate electrode 12 and the W layer 42, and only the gate electrode 12 is fully silicided.

More specifically, first, an alloy target of silicide metal Ni is prepared. The alloy target contains Ni and at least one element selected from the group consisting of Pt, Ta, W, Re, Y, Yb, Al, La, and Ti. The alloy target is NiPt in the present embodiment. The Pt content (concentration) in the target is in the range of 1 atomic % to 10 atomic % and preferably in the range of 2 atomic % to 10 atomic %, and is 5 atomic % in the present embodiment.

The Ni alloy layer 43 having a thickness approximately in the range of 10 nm to 100 nm (about 30 nm in the present embodiment) is deposited on the gate electrode 12 and the W layer 42 by sputtering using the target.

The gate electrode 12 is heat-treated, for example, at a temperature approximately in the range of 200° C. to 500° C. (400° C. in the present embodiment) for 10 to 120 seconds (30 seconds in the present embodiment) to produce a fully silicided gate electrode 44.

Since the source/drain regions 16a and 16b are protected by the W layer 42, only the gate electrode 12 is silicided.

Since the W layer 42 has excellent flatness, even when a plurality of gate electrodes 12 is formed and, moreover, the gate electrodes 12 have nonuniform distribution and different line widths (gate lengths), the gate electrodes 12 are silicided uniformly, thus yielding uniformly and fully silicided gate electrodes 44.

As illustrated in FIG. 18B, an unreacted Ni alloy layer 43, the W layer 42, and the TiN layer 41 are selectively removed by the SPM treatment.

If necessary, a heat treatment at a temperature in the range of 300° C. to 500° C. (400° C. in the present embodiment) for 10 to 120 seconds (30 seconds in the present embodiment) may be performed to stabilize the silicide of the gate electrodes 44.

As illustrated in FIG. 18C, a Ni alloy layer 45 formed of a silicide metal is formed.

More specifically, an alloy target of silicide metal Ni is prepared. The alloy target contains Ni and at least one element selected from the group consisting of Pt, Ta, W, Re, Y, Yb, Al, La, and Ti. The alloy target is NiPt in the present embodiment. The Pt content (concentration) in the target is in the range of 1 atomic % to 10 atomic % and preferably in the range of 2 atomic % to 10 atomic %, and is 5 atomic % in the present embodiment.

The Ni alloy layer 45 having a thickness of about 20 nm is deposited on the semiconductor substrate 1, the fully silicided gate electrode 44, and the sidewall insulating layers 15 by sputtering using the target. The Ni alloy layer 45 may be formed by electron-beam evaporation instead of sputtering. The Ni alloy layer 45 may have a thickness of at least 17 nm and practically at most about 200 nm.

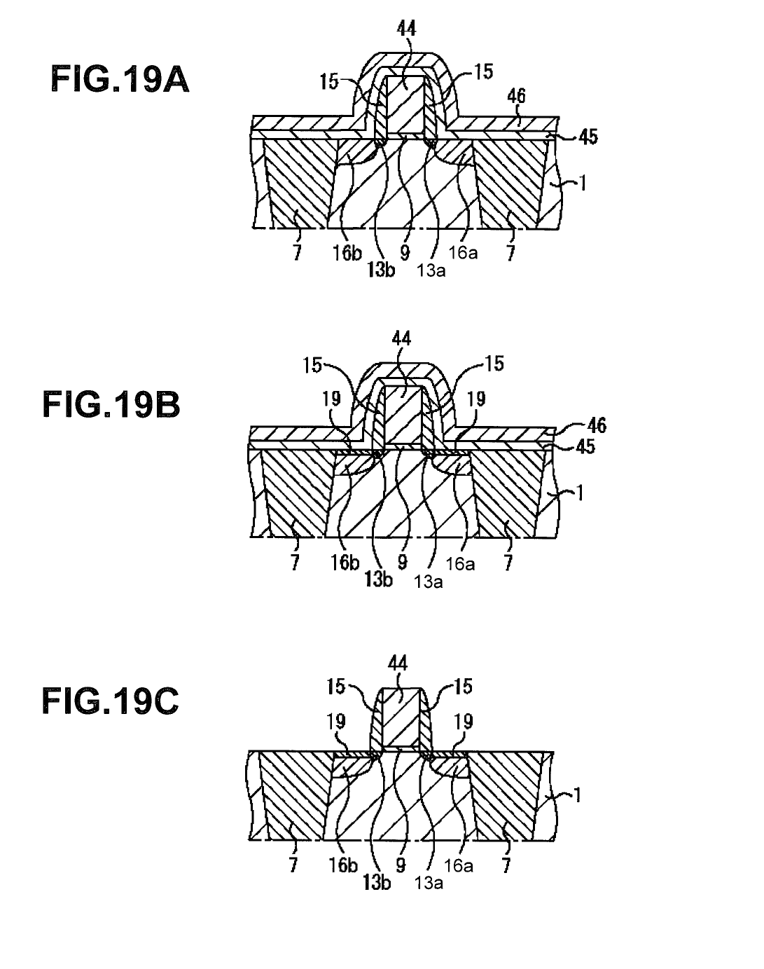

As illustrated in FIG. 19A, a TiN cap layer 46 having a thickness approximately in the range of 5 nm to 50 nm is formed on the Ni alloy layer 45, for example, by sputtering.

The cap layer 46 may be a Ti layer having a thickness approximately in the range of 5 nm to 30 nm. In some cases, the cap layer 46 may be unnecessary.

As illustrated in FIG. 19B, the surfaces of the source/drain regions 16a and 16b are silicided to form (NiPt)₂Si layers 19.

More specifically, the surfaces of the source/drain regions 16a and 16b are silicided by rapid annealing at a relatively low temperature (300° C. or less, for example, 270° C.) for 30 seconds (first silicidation) to form the (NiPt)₂Si layers 19. The fully silicided gate electrode 44 is further silicided negligibly. The rapid annealing may be replaced with furnace annealing (or furnace annealing+rapid heating).

As illustrated in FIG. 19C, the cap layer 46 and an unreacted Ni alloy layer 45 are selectively removed by the SPM treatment.

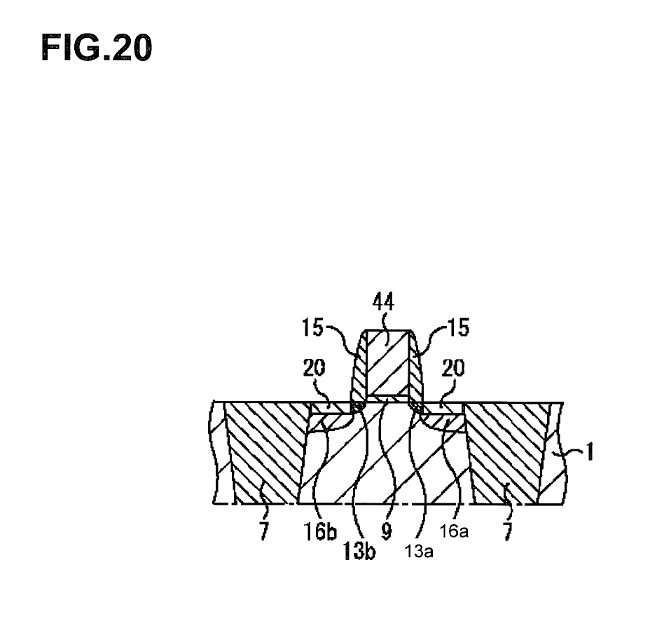

As illustrated in FIG. 20, the (NiPt)₂Si layers 19 are further silicided to form (NiPt)Si layers 20.

More specifically, the (NiPt)₂Si layers 19 are further silicided by rapid annealing at a relatively high temperature (350° C. to 600° C., for example, 400° C.) for 10 to 120 seconds (for example, 30 seconds) (second silicidation) to form the (NiPt)Si layers 20. The fully silicided gate electrode 44 is further silicided negligibly.

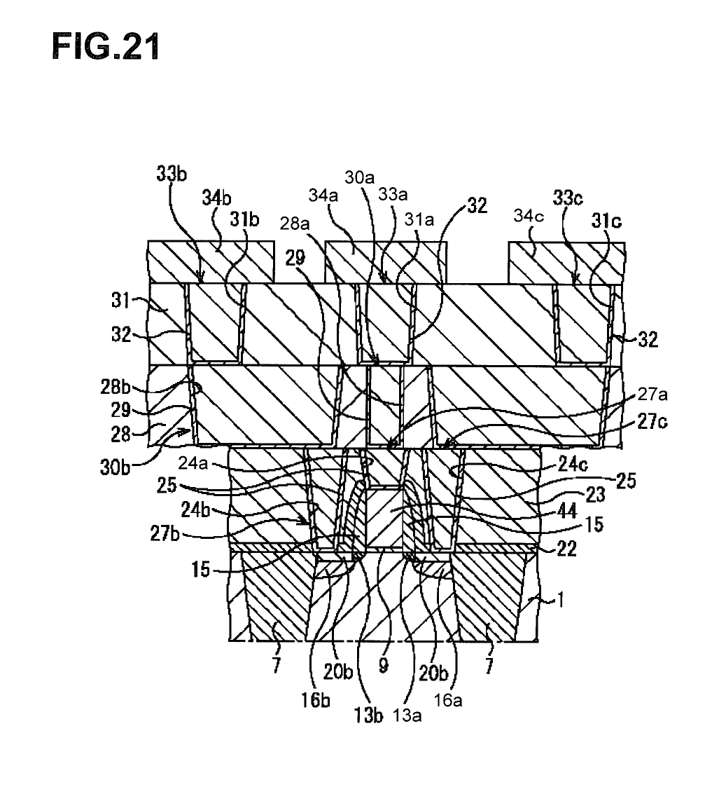

FIG. 21 illustrates a MOS transistor manufactured by the same steps as those illustrated in FIG. 11A to FIG. 14 in the first embodiment. In these steps, the processing temperature is 500° C. or less to prevent the agglomeration of (NiPt)Si in the fully silicided gate electrode 44.

After additional steps, including a step of forming a protective layer (not shown), a MOS transistor according to the present embodiment is manufactured.

Thus, the present embodiment can achieve uniform and satisfactory full silicidation of the gate electrodes 12 without increasing the number of steps.

Furthermore, unlike a related art, the present embodiment does not require a step of forming a cap layer (for example, the cap layer 105 in FIG. 33A) of a gate electrode, thus reducing the number of steps. In addition, ion implantation to the gate electrode (in the present embodiment, for example, ion implantation in FIG. 5A and simultaneous ion implantation in FIGS. 6C and 7C) allows for fine and easy threshold control.

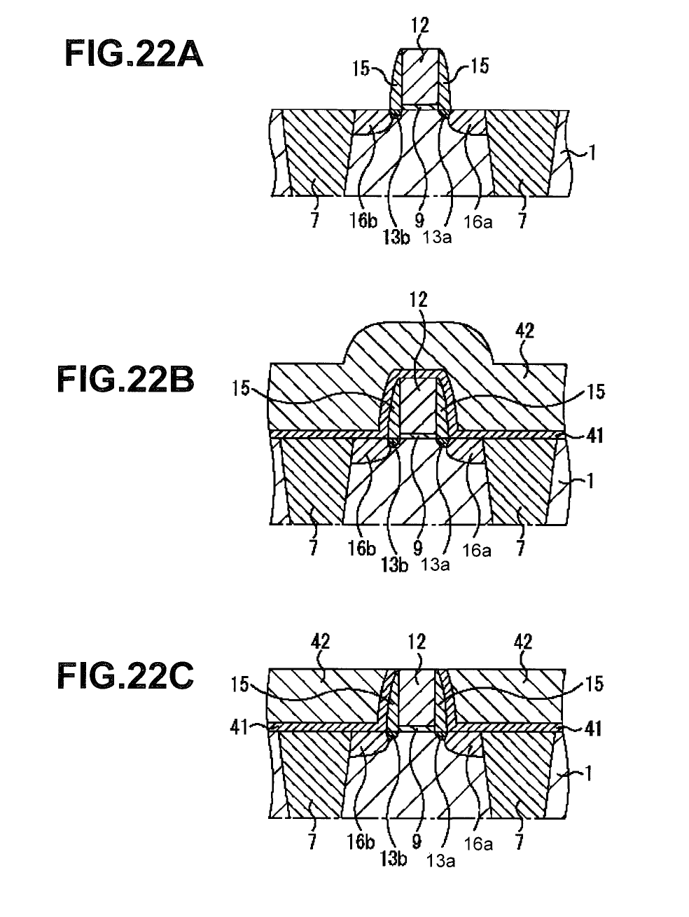

FIGS. 22 to 26 are schematic cross-sectional views illustrating the successive main steps of a method of manufacturing a MOS transistor according to a third embodiment. These drawings are enlarged views of an active region between adjacent device isolation regions for STI.

The step illustrated in FIG. 22A (identical with FIG. 8A) follows the steps in the first embodiment illustrated in FIGS. 1A to 8A.

As illustrated in FIG. 22B, a TiN layer 41 and a W layer 42 are successively formed.

More specifically, first, the TiN layer 41 having a thickness of about 50 nm is formed on the semiconductor substrate 1, the gate electrode 12, and the sidewall insulating layers 15, for example, by sputtering (SIP sputtering in the present embodiment).

Second, an electroconductive layer, such as a W-containing (W or a W alloy) electroconductive layer, (the W layer 42 having a thickness of about 200 nm in the present embodiment) is formed on the TiN layer 41, for example, by CVD. The W layer 42 is formed of a non-silicide metal and has sufficient flatness in subsequent CMP.

As illustrated in FIG. 22C, the W layer 42 and the TiN layer 41 are polished, for example, by CMP to expose the top surface of the gate electrode 12.

A difference in etching rate between W and polycrystalline silicon of the gate electrode 12 is smaller than that between silicon nitride and polycrystalline silicon. Furthermore, w is superior in filling characteristics to silicon nitride. Thus, the W layer 42 has excellent flatness after CMP, without being affected significantly by the distribution or the line width (gate length) of the gate electrodes 12 in CMP.

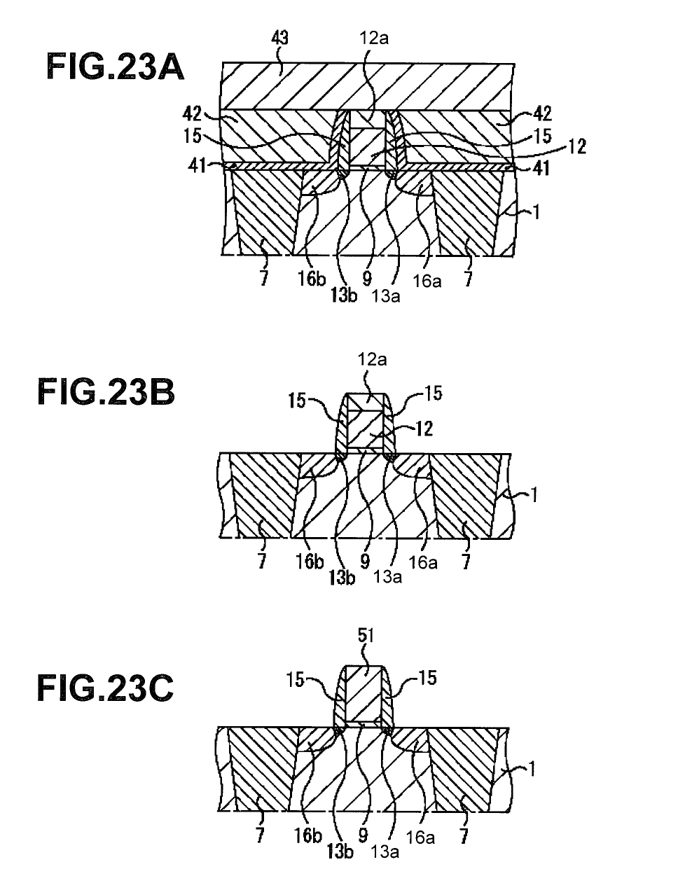

As illustrated in FIG. 23A, a Ni alloy layer 43, which is a silicide metal layer, is formed on the gate electrode 12 and the W layer 42, and only a surface layer 12a of the gate electrode 12 is silicided.

More specifically, first, an alloy target of silicide metal Ni is prepared. The alloy target contains Ni and at least one element selected from the group consisting of Pt, Ta, W, Re, Y, Yb, Al, La, and Ti. The alloy target is NiPt in the present embodiment. The Pt content (concentration) in the target is in the range of 1 atomic % to 10 atomic % and preferably in the range of 2 atomic % to 10 atomic %, and is 5 atomic % in the present embodiment.

The Ni alloy layer 43 having a thickness approximately in the range of 10 nm to 170 nm (about 15 nm in the present embodiment) is deposited on the gate electrode 12 and the W layer 42 by sputtering using the target.

The surface layer 12a of the gate electrode 12 is silicided, for example, at a temperature approximately in the range of 220° C. to 500° C. (270° C. in the present embodiment) for 10 to 120 seconds (30 seconds in the present embodiment).

Since the source/drain regions 16a and 16b are protected by the W layer 42, only the surface layer 12a of the gate electrode 12 is silicided.

Since the W layer 42 has excellent flatness, even when a plurality of gate electrodes 12 is formed and, moreover, the gate electrodes 12 have nonuniform distribution and different line widths (gate lengths), the gate electrodes 12 are silicided uniformly, thus yielding uniformly and fully silicided gate electrodes 44.

As illustrated in FIG. 23B, the W layer 42 and the TiN layer 41 are removed by the SPM treatment.

As illustrated in FIG. 23C, the semiconductor substrate 1 illustrated in FIG. 23B is subjected to flash lamp annealing. Since no silicide layer exists in the source/drain regions 16a and 16b, only the gate electrode 12 including the silicided surface layer 12a is silicided to form a fully silicided gate electrode 51.

This full silicidation is probably effected due to the structure in which the surroundings of the gate electrode 12 retain heat in the flash lamp annealing.

More specifically, since the gate electrode 12 is thermally insulated by the surrounding gate insulating layer 9 and sidewall insulating layers 15, the silicidation of the gate electrode 12 is promoted by the flash lamp annealing.

The conditions for flash lamp annealing are as follows: radiation energy=24 to 28 J/cm², radiation time=0.5 to 1.5 ms, and assist temperature (holding temperature of the semiconductor substrate 1)=300° C. to 450° C. In the present embodiment, flash lamp annealing is performed at an assist temperature of 450° C., a radiation energy of 24 J/cm², and a radiation time of 0.8 ms.

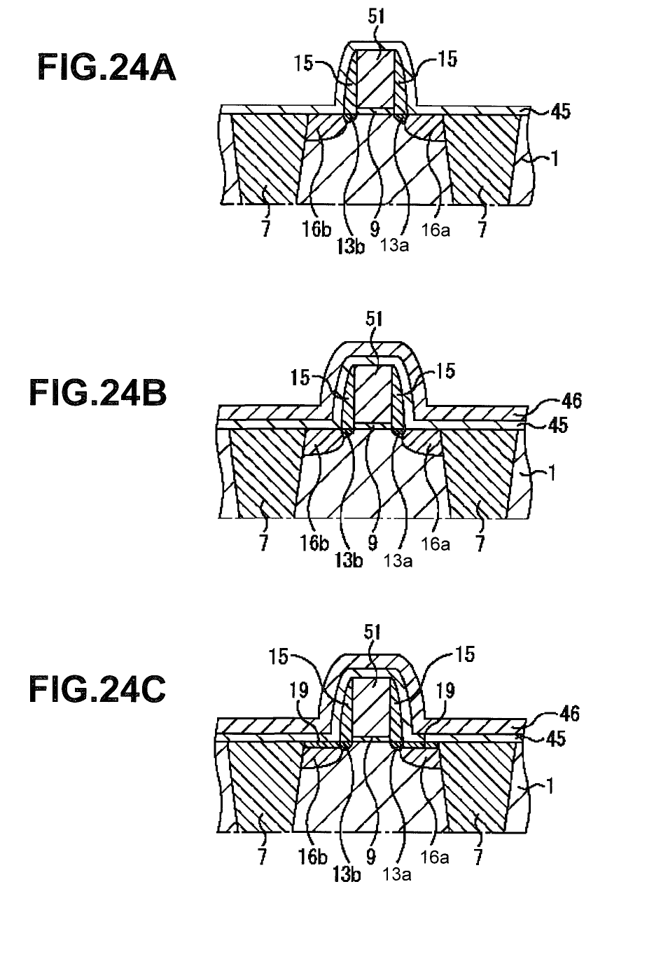

As illustrated in FIG. 24A, a Ni alloy layer 45 formed of a silicide metal is formed.

An alloy target of silicide metal Ni is then prepared. The alloy target contains Ni and at least one element selected from the group consisting of Pt, Ta, W, Re, Y, Yb, Al, La, and Ti. The alloy target is NiPt in the present embodiment. The Pt content (concentration) in the target is in the range of 1 atomic % to 10 atomic % and preferably in the range of 2 atomic % to 10 atomic %, and is 5 atomic % in the present embodiment.

The Ni alloy layer 45 having a thickness of about 20 nm is deposited on the semiconductor substrate 1, the fully silicided gate electrode 51, and the sidewall insulating layers 15 by sputtering using the target. The Ni alloy layer 45 may be formed by electron-beam evaporation instead of sputtering. The Ni alloy layer 45 may have a thickness of at least 17 nm and practically at most about 200 nm.

As illustrated in FIG. 24B, a TiN cap layer 46 having a thickness approximately in the range of 5 nm to 50 nm is formed on the Ni alloy layer 45, for example, by sputtering.

The cap layer 46 may be a Ti layer having a thickness approximately in the range of 5 nm to 30 nm. In some cases, the cap layer 46 may be unnecessary.

As illustrated in FIG. 24C, the surfaces of the source/drain regions 16a and 16b are silicided to form (NiPt)₂Si layers 19.

More specifically, the surfaces of the source/drain regions 16a and 16b are silicided by rapid annealing at a relatively low temperature (300° C. or less, for example, 270° C.) for 30 seconds (first silicidation) to form the (NiPt)₂Si layers 19. The fully silicided gate electrode 51 is further silicided negligibly. The rapid annealing may be replaced with furnace annealing (or furnace annealing+rapid heating).

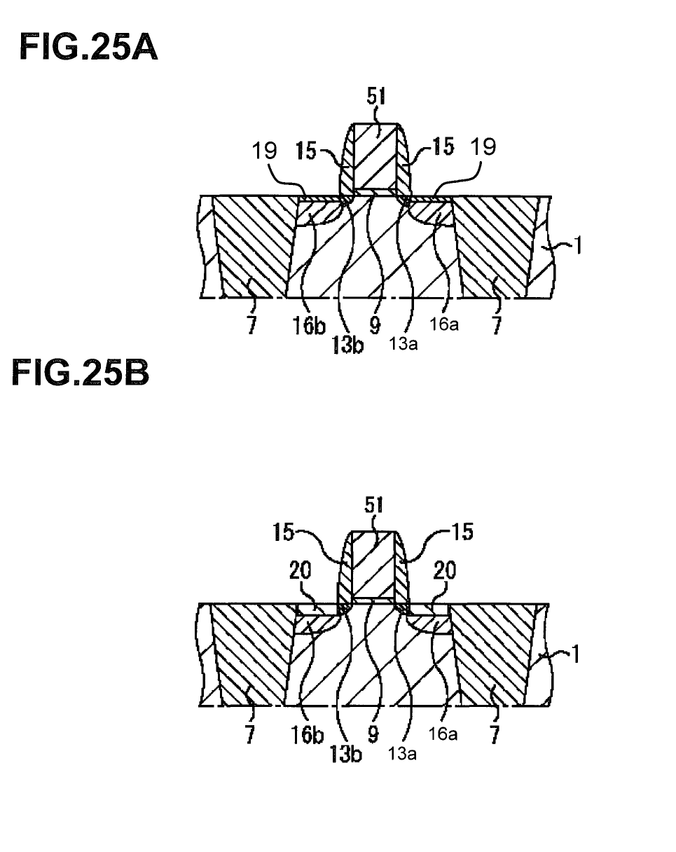

As illustrated in FIG. 25A, the cap layer 46 and an unreacted Ni alloy layer 45 are selectively removed by the SPM treatment.

As illustrated in FIG. 25B, the surfaces of the source/drain regions 16a and 16b are further silicided to form (NiPt)Si layers 20.

More specifically, the (NiPt)₂Si layers 19 are further silicided by rapid annealing at a relatively high temperature (350° C. to 600° C., for example, 400° C.) for 10 to 120 seconds (for example, 30 seconds) (second silicidation) to form the (NiPt)Si layers 20. The fully silicided gate electrode 51 is further silicided negligibly.

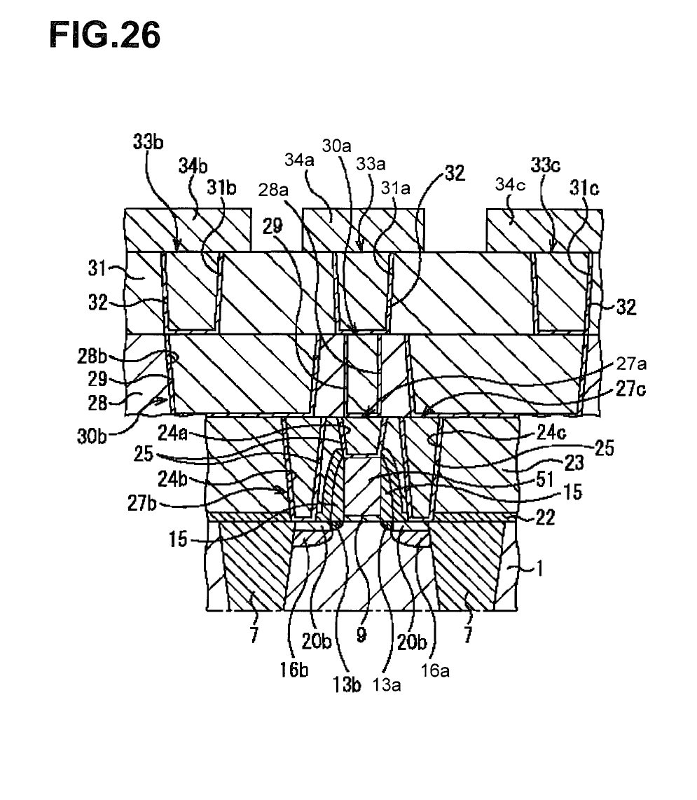

FIG. 26 illustrates a MOS transistor manufactured by the same steps as those illustrated in FIG. 11A to FIG. 14 in the first embodiment. In these steps, the processing temperature is 500° C. or less to prevent the agglomeration of (NiPt)Si of the fully silicided gate electrode 51.

After additional steps, including a step of forming a protective layer (not shown), a MOS transistor according to the present embodiment is manufactured.

Since the fully silicided gate electrode 51 in the MOS transistor is formed by flash lamp annealing, as described above, the gate electrode 51 includes a silicon-rich NiSi₂ phase. This brings about the formation of a NiSi₂-containing layer between the fully silicided gate electrode 51 and the gate insulating layer 9.

In the present embodiment, as illustrated in FIG. 23B, after the W layer 42 and the TiN layer 41 are removed by the SPM treatment, the gate electrode 12 is fully silicided by flash lamp annealing. Alternatively, in the presence of the TiN layer 41 and the W layer 42 (the top surface of the gate electrode 12 is exposed in the W layer 42, as illustrated in FIG. 22C), the Ni alloy layer 45 may be formed on the gate electrode 12 and the W layer 42, and then full silicidation may be performed by flash lamp annealing. In this case, after full silicidation, the W layer 42 and the TiN layer 41 are removed by the SPM treatment.

Thus, the present embodiment can achieve uniform and satisfactory full silicidation of the gate electrodes 12 without increasing the number of steps. Since full silicidation by flash lamp annealing is performed while the surface layer 12a of the gate electrode 12 is silicided, full silicidation of the gate electrode 12 can proceed selectively and uniformly.

The surfaces of the source/drain regions 16a and 16b are silicided independently of full silicidation of the gate electrode 12. Thus, desired fine silicidation of the source/drain regions 16a and 16b can be performed independently of silicidation conditions of the gate electrode 12.

Furthermore, unlike a related art, the present embodiment does not require a step of forming a cap layer (for example, the cap layer 105 in FIG. 33A) of a gate electrode, thus reducing the number of steps. In addition, ion implantation to the gate electrode (in the present embodiment, for example, ion implantation in FIG. 5A and simultaneous ion implantation in FIGS. 6C and 7C) allows for fine and easy threshold control.

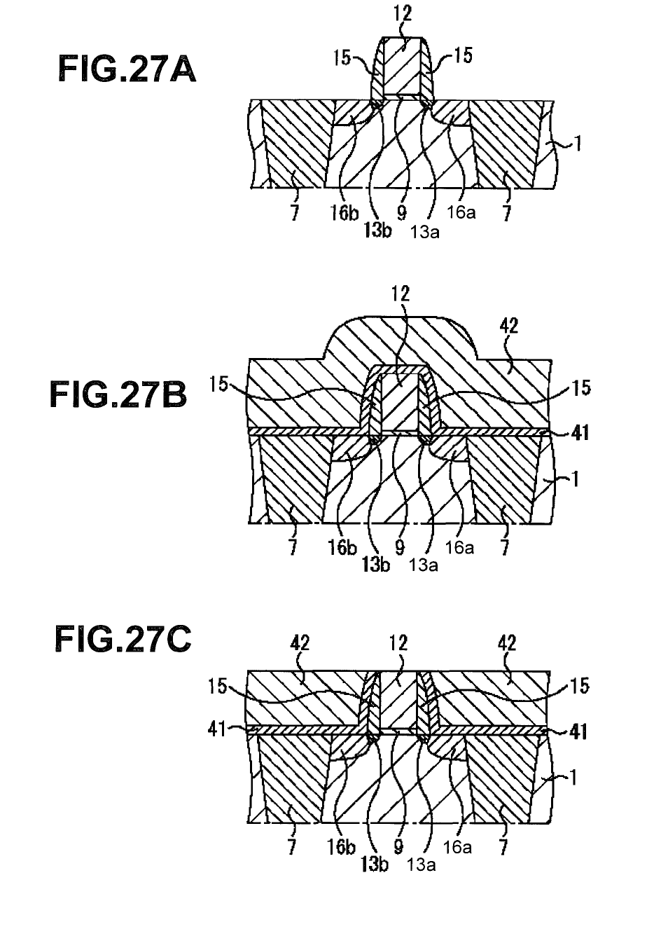

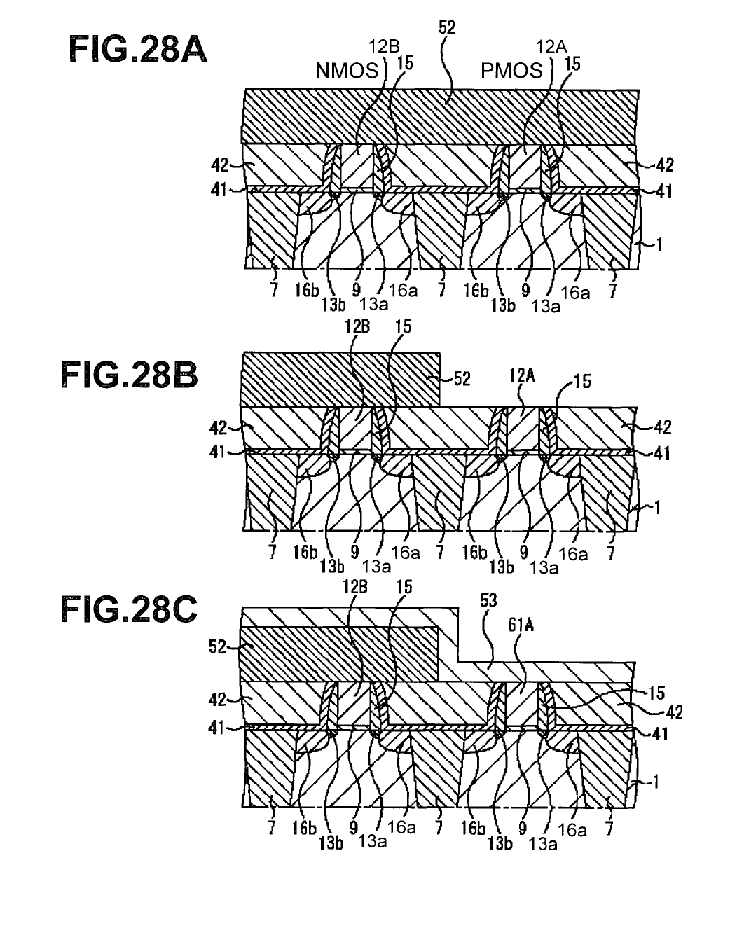

FIGS. 27 to 32 are schematic cross-sectional views illustrating the successive main steps of a method of manufacturing a CMOS transistor according to a fourth embodiment. While FIG. 26 illustrates a single MOS transistor on an enlarged scale, FIGS. 28 to 32 illustrate a CMOS transistor including a p-type MOS transistor and an n-type MOS transistor on an enlarged scale.

The step illustrated in FIG. 27A (identical with FIG. 8A) follows the steps in the first embodiment illustrated in FIGS. 1A to 7C.

As illustrated in FIG. 27B, a TiN layer 41 and a W layer 42 are successively formed.

More specifically, first, the TiN layer 41 having a thickness of about 50 nm is formed on the semiconductor substrate 1, the gate electrode 12, and the sidewall insulating layers 15, for example, by sputtering (SIP sputtering in the present embodiment).

The W layer 42 having a thickness of about 200 nm is formed on the TiN layer 41, for example, by CVD.

As illustrated in FIG. 27C, the W layer 42 and the TiN layer 41 are polished, for example, by CMP to expose the top surface of the gate electrode 12.

A difference in etching rate between W and polycrystalline silicon of the gate electrode 12 is smaller than that between silicon nitride and polycrystalline silicon. Furthermore, w is superior in filling characteristics to silicon nitride. Thus, the W layer 42 has excellent flatness after CMP, without being affected significantly by the distribution or the line width (gate length) of the gate electrodes 12 in CMP.

As illustrated in FIG. 28A, an insulating layer (a silicon nitride layer 52 in the present embodiment) is formed on gate electrodes 12A and 12B and the W layer 42, for example, by CVD. The gate electrode 12A is a gate electrode of the p-type MOS transistor, and the gate electrode 12B is a gate electrode of the n-type MOS transistor.

As illustrated in FIG. 28B, the silicon nitride layer 52 of the p-type MOS transistor is removed by lithography and dry etching, leaving the silicon nitride layer 52 of the n-type MOS transistor.

As illustrated in FIG. 28C, a Ni alloy layer 53, which is a silicide metal layer, is formed on the gate electrode 12A, the W layer 42, and the silicon nitride layer 52, and only the gate electrode 12A is fully silicided.

More specifically, first, the semiconductor substrate 1 is treated with dilute hydrofluoric acid (hereinafter referred to as DHF). An alloy target of silicide metal Ni is then prepared. The alloy target contains Ni and at least one element selected from the group consisting of Pt, Ta, W, and Re. The alloy target is NiPt in the present embodiment. The Pt content (concentration) in the target is in the range of 1 atomic % to 10 atomic % and preferably in the range of 2 atomic % to 10 atomic %, and is 5 atomic % in the present embodiment.

The Ni alloy layer 53 having a thickness approximately in the range of 10 nm to 170 nm (about 40 nm in the present embodiment) is deposited on the gate electrode 12A, the W layer 42, and the silicon nitride layer 52 by sputtering using the target.

The semiconductor substrate 1 including the Ni alloy layer 53 is subjected to flash lamp annealing. Since no silicide layer exists in the source/drain regions 16a and 16b of the p-type MOS transistor and in the n-type MOS transistor, each covered with the TiN layer 41 and the W layer 42, only the gate electrode 12A is silicided to form a fully silicided gate electrode 61A.

This full silicidation is probably effected due to the structure in which the surroundings of the gate electrode 12A retain heat in the flash lamp annealing.

More specifically, since the gate electrode 12A is thermally insulated by the surrounding gate insulating layer 9 and sidewall insulating layers 15, the silicidation of the gate electrode 12A is promoted by the flash lamp annealing.

The conditions for flash lamp annealing are as follows: radiation energy=24 to 28 J/cm², radiation time=0.5 to 1.5 ms, and assist temperature (holding temperature of the semiconductor substrate 1)=300° C. to 450° C. In the present embodiment, flash lamp annealing is performed at an assist temperature of 400° C., a radiation energy of 26 J/cm², and a radiation time of 0.8 ms.

Instead of flash lamp annealing, lamp annealing or furnace annealing, for example, at a temperature of 400° C. for 120 seconds may be performed for full silicidation of the gate electrode 12A.

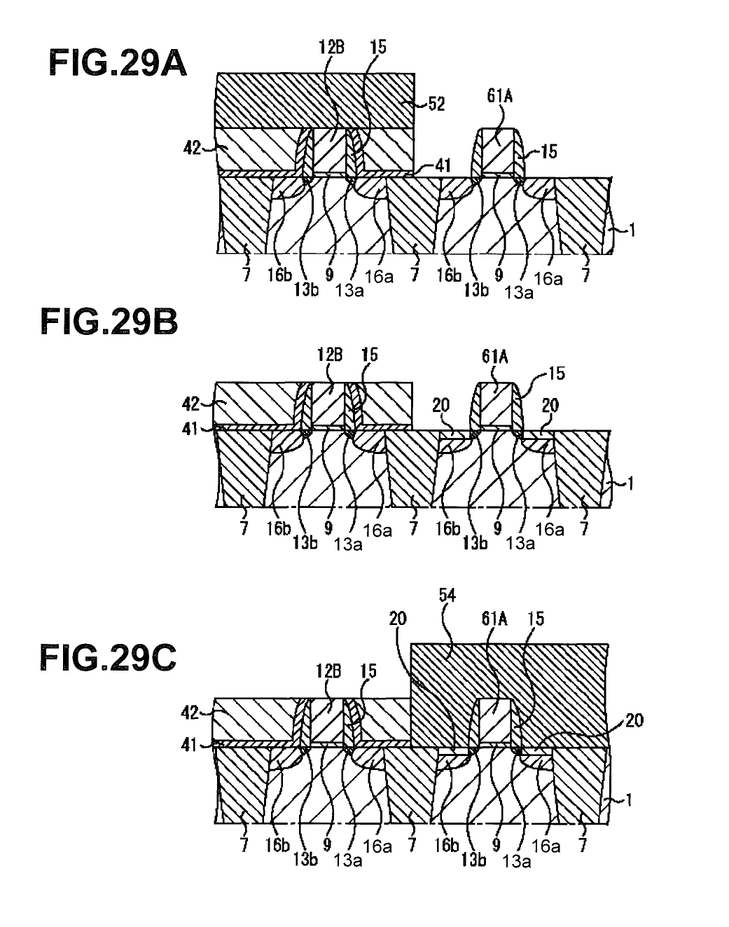

As illustrated in FIG. 29A, an unreacted Ni alloy layer 53, and the W layer 42 and the TiN layer 41 in the p-type MOS transistor are selectively removed by the SPM treatment.

As illustrated in FIG. 29B, the surfaces of the source/drain regions 16a and 16b in the p-type MOS transistor are further silicided to form (NiPt)Si layers 20.

More specifically, the silicon nitride layer 52 in the n-type MOS transistor is removed by lithography and dry etching. Through the steps illustrated, for example, in FIGS. 24A to 25B in the third embodiment, the surfaces of the source/drain regions 16a and 16b in the p-type MOS transistor are silicided to form (NiPt)Si layers 20.

As illustrated in FIG. 29C, a compressive silicon nitride layer 54 is formed on the p-type MOS transistor.

More specifically, first, an insulating layer that can apply a compressive stress to the outside (compressive silicon nitride layer 54 in the present embodiment) is deposited on the semiconductor substrate 1 using a silane gas (such as SiH₄, SiH₂Cl₂, Si₂H₄, or Si₂H₆) and NH₃ in combination with, for example, about 1 to 50 standard cubic centimeters per minute (sccm) of an organosilane.

The compressive silicon nitride layer 54 in the n-type MOS transistor is removed by lithography and dry etching, leaving the compressive silicon nitride layer 54 in the p-type MOS transistor.

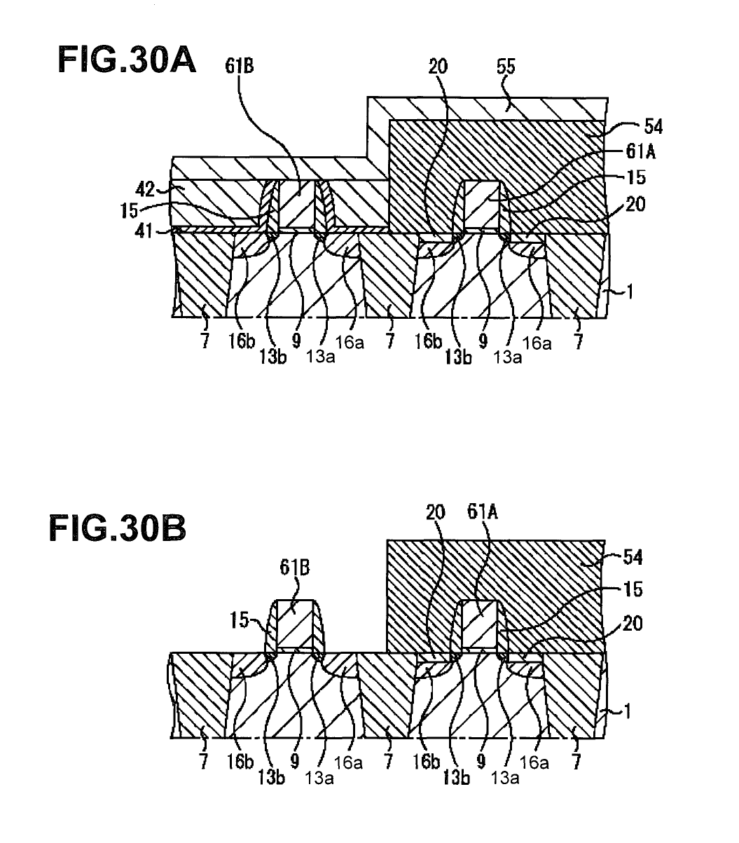

As illustrated in FIG. 30A, a Ni alloy layer 55, which is a silicide metal layer, is formed on the gate electrode 12B, the W layer 42, and the compressive silicon nitride layer 54, and only the gate electrode 12B is fully silicided.

More specifically, first, the semiconductor substrate 1 is treated with DHF. An alloy target of silicide metal Ni is then prepared. The alloy target contains Ni and at least one element selected from the group consisting of Y, Yb, Al, La, and Ti. The alloy target is NiY in the present embodiment. The Y content (concentration) in the target is in the range of 1 atomic % to 10 atomic % and preferably in the range of 2 atomic % to 10 atomic %, and is 5 atomic % in the present embodiment.

The Ni alloy layer 55 having a thickness approximately in the range of 10 nm to 170 nm (about 40 nm in the present embodiment) is deposited on the gate electrode 12B, the W layer 42, and the compressive silicon nitride layer 54 by sputtering using the target.

The semiconductor substrate 1 including the Ni alloy layer 55 is subjected to flash lamp annealing. Since no silicide layer exists in the source/drain regions 16a and 16b of the n-type MOS transistor and in the p-type MOS transistor, each covered with the compressive silicon nitride layer 54, only the gate electrode 12B is silicided to form a fully silicided gate electrode 61B.

This full silicidation is probably effected due to the structure in which the surroundings of the gate electrode 12B retain heat in the flash lamp annealing.

More specifically, since the gate electrode 12B is thermally insulated by the surrounding gate insulating layer 9 and sidewall insulating layers 15, the silicidation of the gate electrode 12B is promoted by the flash lamp annealing.

The conditions for flash lamp annealing are as follows: radiation energy=24 to 28 J/cm², radiation time=0.5 to 1.5 ms, and assist temperature (holding temperature of the semiconductor substrate 1)=300° C. to 450° C. In the present embodiment, flash lamp annealing is performed at an assist temperature of 400° C., a radiation energy of 26 J/cm², and a radiation time of 0.8 ms.

Instead of flash lamp annealing, lamp annealing or furnace annealing, for example, at a temperature of 400° C. for 120 seconds may be performed for full silicidation of the gate electrode 12B.

As illustrated in FIG. 30B, an unreacted Ni alloy layer 55, the W layer 42, and the TiN layer 41 are selectively removed by the SPM treatment.

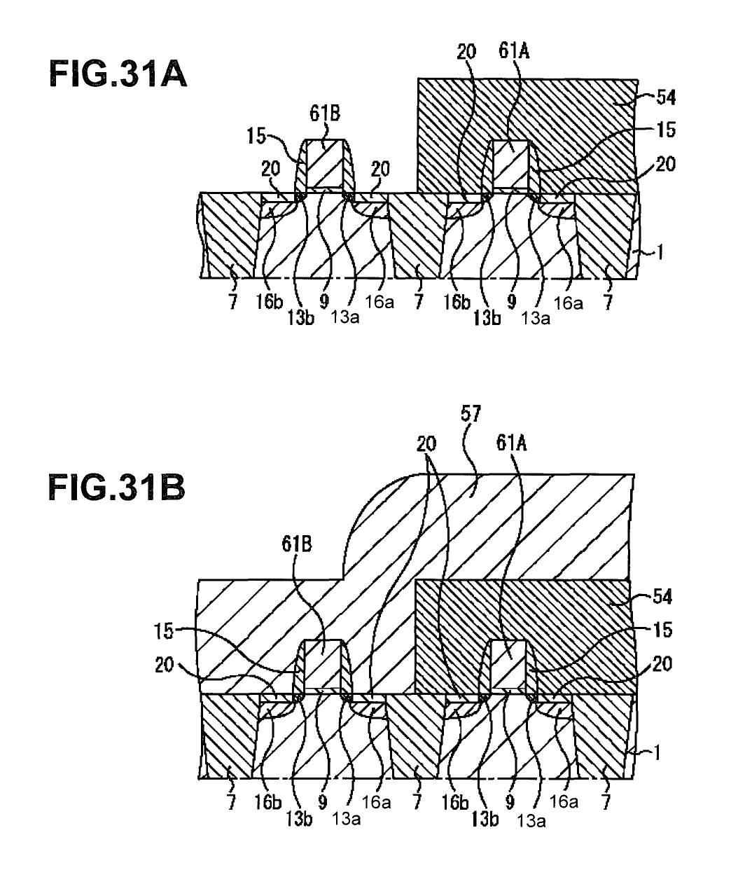

As illustrated in FIG. 31A, the surface of the source/drain regions 16a and 16b in the n-type MOS transistor is silicided.

More specifically, through the steps illustrated, for example, in FIGS. 24A to 25B in the third embodiment (in a step corresponding to that illustrated in FIG. 24C, a (NiY)₂Si layer is formed), the surfaces of the source/drain regions 16a and 16b in the n-type MOS transistor are silicided to form (NiY)Si layers 20. Y may be replaced by La, Yb, or Al.

As illustrated in FIG. 31B, an insulating layer that can apply a tensile stress to the outside (tensile silicon nitride layer 57 in the present embodiment) is formed by depositing silicon nitride on the semiconductor substrate 1 and the compressive silicon nitride layer 54 using a silane gas (such as SiH₄, SiH₂Cl₂, Si₂H₄, or Si₂H₆) and NH₃ and by irradiating the silicon nitride with ultraviolet rays generated by a high-pressure mercury lamp.

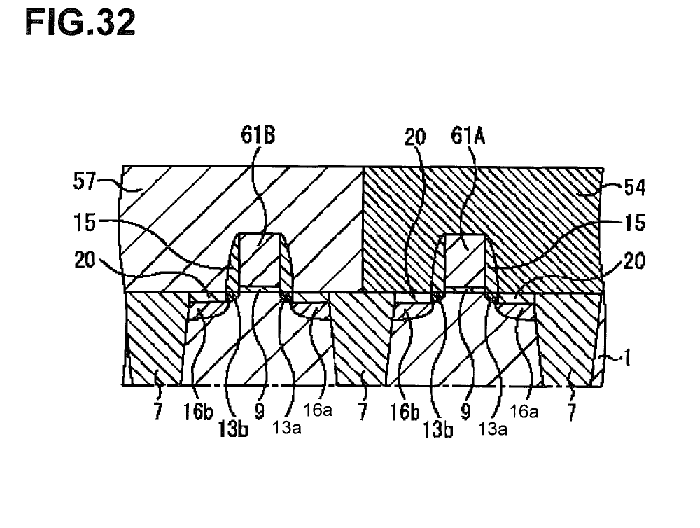

As illustrated in FIG. 32, the tensile silicon nitride layer 57 in the p-type MOS transistor is removed by lithography and dry etching, leaving the tensile silicon nitride layer 57 in the n-type MOS transistor.

Through the steps corresponding to those illustrated in FIGS. 11C to 14 in the first embodiment (in a step corresponding to that illustrated in FIG. 11C, connecting holes are formed in the compressive silicon nitride layer 54 and the tensile silicon nitride layer 57) and additional steps, including a step of forming a protective layer (not shown), a CMOS transistor according to the present embodiment is manufactured.

Since the fully silicided gate electrodes 61A and 61B in the CMOS transistor is formed by flash lamp annealing, as described above, the gate electrodes 61A and 61B include a silicon-rich NiSi₂ phase. This brings about the formation of NiSi₂-containing layers between the fully silicided gate electrodes 61A and 61B and the gate insulating layers 9.

As described above, the present embodiment can achieve uniform and satisfactory full silicidation of the gate electrodes 12A and 12B without increasing the number of steps.

The surfaces of the source/drain regions 16a and 16b are silicided independently of full silicidation of the gate electrodes 12A and 12B. Thus, desired fine silicidation of the source/drain regions 16a and 16b can be performed independently of silicidation conditions of the gate electrodes 12A and 12B.

Furthermore, unlike a related art, the present embodiment does not require a step of forming a cap layer (for example, the cap layer 105 in FIG. 33A) of a gate electrode, thus reducing the number of steps. In addition, ion implantation to the gate electrode (in the present embodiment, for example, ion implantation in FIG. 5A and simultaneous ion implantation in FIGS. 6C and 7C) allows for fine and easy threshold control.

What is claimed is:

1. A method of manufacturing a semiconductor device comprising:
forming a silicon-containing layer over a semiconductor substrate;
forming a metal layer over the semiconductor substrate and the silicon-containing layer;
forming a silicide-containing layer over the semiconductor substrate and the silicon-containing layer by heat treatment of the semiconductor substrate and the silicon-containing layer; and
applying flash annealing to the silicide-containing layer.

2. The method according to claim 1, wherein the metal layer comprises nickel or nickel alloy.

3. The method according to claim 1, wherein the nickel alloy comprises at least one element selected from the group consisting of Pt, Ta, W, Re, Y, Yb, Al, La, and Ti, and the nickel alloy contains the element in a range from 2 atomic percent to 10 atomic percent.

4. The method according to claim 1, wherein the semiconductor substrate comprises silicon, the semiconductor substrate comprises a pair of impurity diffusion regions disposed in the surface of the semiconductor substrate at both sides of the silicide-containing layer, and the forming the silicide-containing layer over the semiconductor substrate and the silicon-containing layer by the heat treatment of the semiconductor substrate and the silicon-containing layer performs silicidation at least part of impurity diffusion regions.

5. The method according to claim 1, further comprising forming a sidewall spacer over both side of the silicide-containing layer before the applying the flash annealing to the silicide-containing layer.

6. The method according to claim 1, wherein the applying the flash annealing to the silicide-containing layer is performed in a range from 24 J/cm² to 28 J/cm² of radiation energy, for a time from 0.5 ms to 1.5 ms, at a temperature range from 300° C. to 450° C.

7. A method of manufacturing a semiconductor device comprising:
forming a silicon-containing layer over a semiconductor substrate;
forming a protective layer over the semiconductor substrate to cover the silicon-containing layer, the protective layer including a metal,
applying chemical mechanical polishing to the protective layer to expose the top surface of the silicon-containing layer;
forming a metal layer over the exposed surface of the silicon-containing layer; and
forming a silicide layer in at least part of the silicon-containing layer by heat treatment of the silicon-containing layer.

8. The method according to claim 7, wherein the forming the silicide layer over the semiconductor substrate performs silicidation at least part of the silicon-containing layer while the top surface of the silicon-containing layer is exposed from the protective layer, and applies flash annealing to the silicide-containing layer, at least part of the silicon-containing layer being performed silicidation while the protective layer is removed from the semiconductor substrate.

9. The method according to claim 7, wherein the metal layer comprises nickel or nickel alloy.

10. The method according to claim 7, wherein the nickel alloy comprises at least one element selected from the group consisting of Pt, Ta, W, Re, Y, Yb, Al, La, and Ti, and the nickel alloy contains the element in a range from 2 atomic percent to 10 atomic percent.

11. The method according to claim 8, wherein the semiconductor substrate comprises a pair of impurity diffusion regions disposed in the surface of the semiconductor substrate at both sides of the silicide-containing layer, and the forming the silicide-containing layer over the semiconductor substrate and the silicon-containing layer by the heat treatment of the semiconductor substrate and the silicon-containing layer performs silicidation at least part of impurity diffusion regions.

12. The method according to claim 8, further comprising forming a sidewall spacer over both side of the silicide-containing layer before the applying flash annealing to the silicide-containing layer.

13. The method according to claim 8, wherein the applying the flash annealing to the silicide-containing layer is performed in a range from 24 J/cm² to 28 J/cm² of radiation energy, for a time from 0.5 ms to 1.5 ms, at a temperature range from 300° C. to 450° C.

14. A method of manufacturing a semiconductor device, comprising:
forming a gate electrode over a semiconductor substrate, the gate electrode comprising silicon;
forming a protective layer over the semiconductor substrate to cover the gate electrode, the protective layer containing non-silicide metal;
applying chemical mechanical polishing to the protective layer to expose the top surface of the gate electrode;
forming a metal layer over the exposed surface of the gate electrode layer, the metal layer comprising nickel; and
forming a silicide layer in at least part of the gate electrode by heat treatment of the silicon-containing layer.

15. The method according to claim 14, wherein the forming the silicide layer over the gate electrode performs silicidation at least part of the gate electrode while the top surface of the gate electrode is exposed from the protective layer, applies flash annealing to the gate electrode, at least part of the gate electrode being performed silicidation while the protective layer is removed from the semiconductor substrate.

16. The method according to claim 14, wherein the metal layer comprises nickel or nickel alloy.

17. The method according to claim 16, wherein the nickel alloy comprises at least one element selected from the group consisting of Pt, Ta, W, Re, Y, Yb, Al, La, and Ti, and the nickel alloy contains the element in a range from 2 atomic percent to 10 atomic percent.

18. The method according to claim 15, wherein the semiconductor substrate comprises a pair of impurity diffusion regions disposed in the surface of the semiconductor substrate at both sides of the silicide-containing layer, and the forming the silicide-containing layer over the semiconductor substrate and the silicon-containing layer by the heat treatment of the semiconductor substrate and the silicon-containing layer performs silicidation at least part of impurity diffusion regions.

19. The method according to claim 15, further comprising forming a sidewall spacer on both side of the silicide-containing layer before the applying the flash annealing to the silicide-containing layer.

20. The method according to claim 15, wherein the applying the flash annealing to the silicide-containing layer is performed in a range from 24 J/cm² to 28 J/cm² of radiation energy, for a time from 0.5 ms to 1.5 ms, and at a temperature from 300° C. to 450° C.
